(19) United States
(12) Patent Application Publication
(10) Pub. No.: US 2025/0220929 A1
(43) Pub. Date: Jul. 3, 2025

(54) SEMICONDUCTOR DEVICES

(71) Applicant: SAMSUNG ELECTRONICS CO., LTD., Suwon-si (KR)

(72) Inventors: Junsoo Kim, Suwon-si (KR); Moonyoung Jeong, Suwon-si (KR); Sungho Jang, Suwon-si (KR); Jinyang Kim, Suwon-si (KR); Kiseok Lee, Suwon-si (KR)

(21) Appl. No.: 18/951,261

(22) Filed: Nov. 18, 2024

(30) Foreign Application Priority Data
Dec. 29, 2023 (KR) 10-2023-0196196

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2225/06541; H01L 2924/1431; H01L 2924/1436

(57) ABSTRACT

A semiconductor device includes a first chip structure; and a second chip structure on the first chip structure. The first chip structure includes a base substrate, a memory structure on the base substrate, a first substrate on the memory structure, first through-vias penetrating the first substrate, a first wiring structure disposed on the first substrate; first bonding pads on an upper surface of the first wiring structure, and a hydrogen-containing insulating layer disposed in a region adjacent to the memory structure in the first chip structure. The second chip structure includes a second substrate, peripheral circuit transistors and a lower wiring structure disposed on a lower surface of the second substrate; second bonding pads electrically connected to the lower wiring layer, and bonded to the first bonding pads, respectively; and an upper wiring structure.

### CROSS-REFERENCE TO RELATED APPLICATION(S)

This application claims the benefit of priority to Korean Patent Application No. 10-2023-0196196, filed on Dec. 29, 2023, in the Korean Intellectual Property Office, the disclosure of which is incorporated herein by reference in its entirety.

### BACKGROUND

As the electronics industry develops, demand for high reliability, high speed, and/or multifunctionality of a semiconductor device has increased. To meet such characteristics, structures in a semiconductor device have been complex, and semiconductor devices have become highly integrated.

### SUMMARY

Some implementations of the present disclosure is provide semiconductor devices having improved reliability, and methods of manufacturing the same

According to some implementations, a semiconductor device includes a first chip structure; and a second chip structure on the first chip structure, wherein the first chip structure includes a base substrate, a memory structure disposed on the base substrate, a first substrate disposed on the memory structure, first through-vias penetrating the first substrate and electrically connected to the memory structure, a first wiring structure disposed on the first substrate and including a first wiring layer electrically connected to the memory structure through the first through-vias; first bonding pads disposed on an upper surface of the first wiring structure and electrically connected to the first wiring layer, and a hydrogen-containing insulating layer disposed in a region adjacent to the memory structure in the first chip structure, and wherein the second chip structure includes a second substrate, peripheral circuit transistors disposed on a lower surface of the second substrate, a lower wiring structure disposed on the lower surface of the second substrate and including a lower wiring layer electrically connected to the peripheral circuit transistors; second bonding pads disposed on a lower surface of the lower wiring structure, electrically connected to the lower wiring layer, and bonded to the first bonding pads, respectively; second through-vias penetrating the second substrate and electrically connected to the lower wiring layer, and an upper wiring structure disposed on an upper surface of the second substrate and having an upper wiring layer electrically connected to the lower wiring layer through the second through-vias.

According to some implementations, a semiconductor device includes a first chip structure; and a second chip structure on the first chip structure, wherein the first chip structure includes a base substrate having an upper surface on which a hydrogen-containing insulating layer is disposed, a memory structure disposed on the base substrate and in contact with the hydrogen-containing insulating layer, a first wiring structure disposed on the memory structure and including a first wiring layer electrically connected to the memory structure, and first bonding pads disposed on an upper surface of the first wiring structure and electrically connected to the first wiring layer, and wherein the second chip structure includes a second substrate, peripheral circuit transistors disposed on a lower surface of the second substrate, a lower wiring structure disposed on the lower surface of the second substrate, including a lower wiring layer electrically connected to the peripheral circuit transistors, and bonded to the first wiring structure; second bonding pads disposed on a lower surface of the lower wiring structure, electrically connected to the lower wiring layer, and bonded to the first bonding pads, respectively; second through-vias penetrating the second substrate and electrically connected to the lower wiring layer, and an upper wiring structure disposed on an upper surface of the second substrate and including an upper wiring layer electrically connected to the lower wiring layer through the second through-vias.

According to some implementations, a semiconductor device includes a second chip structure; and a first chip structure on the second chip structure, wherein the second chip structure includes a base substrate, a second substrate having a lower surface opposing an upper surface of the base substrate, peripheral circuit transistors disposed on the lower surface of the second substrate, a second lower wiring structure disposed between an upper surface of the base substrate and the lower surface of the second substrate and including a second lower wiring layer electrically connected to the peripheral circuit transistors; second through-vias penetrating the second substrate and electrically connected to the second lower wiring layer, a second upper wiring structure disposed on an upper surface of the second substrate and having a second upper wiring layer electrically connected to the second lower wiring layer through the second through-vias; second bonding pads disposed on an upper surface of the second upper wiring structure and electrically connected to the second upper wiring layer, and wherein the first chip structure includes a first substrate having an upper surface on which a hydrogen-containing insulating layer is disposed, a memory structure disposed on a lower surface of the first substrate, a first lower wiring structure disposed on a lower surface of the memory structure, including a first lower wiring layer electrically connected to the memory structure, and bonded to the second upper wiring structure, first bonding pads disposed on a lower surface of the first lower wiring structure, electrically connected to the first lower wiring layer, and bonded to the second bonding pads, respectively, first through-vias penetrating the first substrate and electrically connected to the memory structure, and a first upper wiring structure disposed on the first substrate and having a first upper wiring layer electrically connected to the memory structure through the first through-vias.

According to some implementations, a method of manufacturing a semiconductor device includes forming a memory structure on a first substrate; preparing a base substrate having an upper surface on which a hydrogen-containing insulating layer is disposed; primarily bonding the memory structure together with the first substrate to the upper surface of the base substrate; grinding the first substrate after the primary bonding; forming a first through-vias penetrating the first substrate and electrically connected to the memory structure; forming a first wiring structure including a first wiring layer electrically connected to the first through-vias on the first substrate; forming first bonding pads electrically connected to the first wiring layer on an upper surface of the first wiring structure; forming peripheral circuit transistors and a lower wiring structure on the second substrate, wherein the lower wiring structure includes a lower wiring layer electrically connected to the peripheral circuit transistors; forming second bonding pads electrically connected to the lower wiring layer on a lower surface of the lower wiring structure; secondarily bonding the upper surface of the lower wiring structure to the upper surface of the first wiring structure by bonding the first bonding pads to the second bonding pads; forming second through-vias penetrating the second substrate and electrically connected to the lower wiring layer; and forming an upper wiring structure including an upper wiring layer electrically connected to the second through-vias on the second substrate.

According to some implementations, a method of manufacturing a semiconductor device includes forming a memory structure on a first substrate; forming a first lower wiring structure including a first lower wiring layer electrically connected to the memory structure on the memory structure; forming first bonding pads electrically connected to the first lower wiring layer on an lower surface of the first lower wiring structure; forming peripheral circuit transistors and a second lower wiring structure on the second substrate, wherein the second lower wiring structure includes a second lower wiring layer electrically connected to the peripheral circuit transistors; primarily bonding the second lower wiring structure to an upper surface of the base substrate together with the second substrate on which the peripheral circuit transistor is formed; grinding the second substrate after the primary bonding; forming second through-vias penetrating the second substrate and electrically connected to the second lower wiring layer; forming a second upper wiring structure including a second upper wiring layer electrically connected to the second through-vias on the second substrate; forming second bonding pads electrically connected to the second upper wiring layer on an upper surface of the second upper wiring structure; secondarily bonding the lower surface of the first lower wiring structure to the upper surface of the second upper wiring structure by bonding the first bonding pads to the second bonding pads; grinding the first substrate after the secondarily bonding; forming a hydrogen-containing insulating layer on a ground surface of the first substrate; forming first through-vias penetrating the first substrate and electrically connected to the first lower wiring layer; and forming a first upper wiring structure including a first upper wiring layer electrically connected to the first through-vias on the first substrate.

### BRIEF DESCRIPTION OF DRAWINGS

The foregoing and other aspects, features, and advantages according to the present disclosure will be more clearly understood from the following detailed description, taken in combination with the accompanying drawings, in which:

FIG. 1A is a perspective diagram illustrating a semiconductor device according to some implementations of the present disclosure;

FIG. 1B is a plan diagram illustrating a portion of a bank in FIG. 1A;

FIG. 2A is a cross-sectional diagram illustrating a semiconductor device according to some implementations of the present disclosure;

FIG. 2B is a graph of hydrogen content distribution according to a stacking direction of the semiconductor device in FIG. 2A;

FIG. 3 is an enlarged diagram illustrating portion “A1” of the semiconductor device in FIG. 2A;

FIGS. 4A and 4B are enlarged diagrams illustrating examples of portion “A2” of the semiconductor device in FIG. 2A;

FIGS. 5A and 5B are plan diagrams illustrating a base substrate;

FIG. 6A is a cross-sectional diagram illustrating a semiconductor device according to some implementations of the present disclosure;

FIG. 6B is a graph of hydrogen content distribution according to a stacking direction of the semiconductor device in FIG. 6A;

FIG. 7 is an enlarged diagram illustrating portion “B” of the semiconductor device in FIG. 6A;

FIG. 8 is a cross-sectional diagram illustrating a semiconductor device according to some implementations of the present disclosure;

FIG. 9 is a flowchart illustrating a method of manufacturing a semiconductor device according to some implementations of the present disclosure;

FIGS. 10A to 10D are cross-sectional diagrams illustrating a process of manufacturing a lower chip structure according to some implementations of the present disclosure;

FIGS. 11A and 11B are cross-sectional diagrams illustrating a process of manufacturing an upper chip structure according to some implementations of the present disclosure;

FIGS. 12A to 12C are cross-sectional diagrams illustrating a bonding process and a wiring structure according to some implementations of the present disclosure;

FIGS. 13A to 13D are cross-sectional diagrams illustrating processes of a method of manufacturing a semiconductor device according to some implementations of the present disclosure;

FIG. 14 is a flowchart illustrating a method of manufacturing a semiconductor device according to some implementations of the present disclosure;

FIGS. 15A to 15E are cross-sectional diagrams illustrating processes of manufacturing a semiconductor device according to some implementations of the present disclosure;

FIG. 16 is a cross-sectional diagram illustrating a semiconductor device according to some implementations of the present disclosure;

FIGS. 17A to 17C are cross-sectional diagrams illustrating a semiconductor device according to some implementations of the present disclosure; and

FIGS. 18A and 18B are block diagrams illustrating a semiconductor device according to some implementations of the present disclosure.

### DETAILED DESCRIPTION

Hereinafter, examples according to the present disclosure will be described with reference to the accompanying drawings.

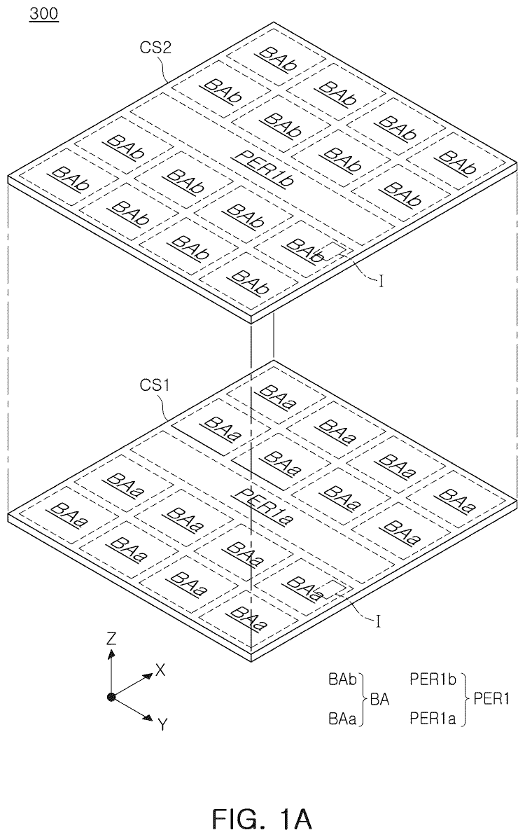

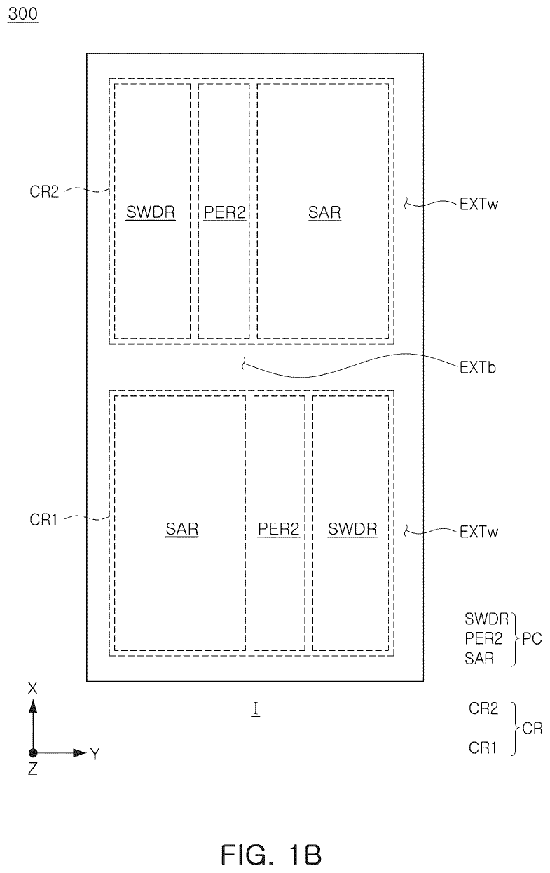

FIG. 1A is a perspective diagram illustrating a semiconductor device according to some implementations. FIG. 1B is a plan-view diagram illustrating a portion of a bank in FIG. 1A.

Referring to FIGS. 1A and 1B, the semiconductor device 300 includes a first chip structure CS1 (sometimes referred to as “lower chip structure”), and a second chip structure CS2 (sometimes referred to as “upper chip structure”) stacked in the vertical direction (Z-direction) on the first chip structure CS1. The labels “first” and “second” and “CS1” and “CS2” are not intended to be limiting of the relative arrangements of the chip structures; in some implementations, a first chip structure CS1 can be an upper chip structure, and a second chip structure CS2 can be a lower chip structure.

The semiconductor device 300 includes a plurality of banks BA and a first peripheral region PER1. Each of the plurality of banks BA includes a lower region BAa in the first chip structure CS1 and an upper region BAb in the second chip structure CS2. Similarly, the first peripheral region PER1 includes the first lower region PER1a in the first chip structure CS1 and the first upper region PER1b in the second chip structure CS2. The first peripheral region PER1 may be configured as a peripheral circuit region in which peripheral circuits for input/output of data or commands and/or power/ground input are disposed.

Referring to FIG. 1B, portion “I” of the bank BA in FIG. 1A is illustrated in an enlarged manner. Each of the banks BA may include memory regions CR, extension regions EXTb and EXTw adjacent to the memory regions CR, and peripheral circuit regions PC vertically overlapping the memory regions CR. The memory regions CR and the extension regions EXTb and EXTw may be disposed in the lower regions BAa of the banks BA of the first chip structure CS1, and the peripheral circuit regions PC may be disposed in the upper regions BAb of the banks BA of the second chip structure CS2.

Each of the memory regions CR may include cell switching devices including gate electrodes, bitlines electrically connected to the cell switching devices, and data storage structures electrically connected to the cell switching devices. The gate electrodes of the cell switching devices may be configured as wordlines.

The extension regions EXTb and EXTw may include the first extension region EXTb adjacent to the memory regions CR in the first direction (X-direction), and the second extension region EXTw adjacent to the memory regions CR in the second direction (Y-direction). The first extension region EXTb adjacent to the memory regions CR in the first direction (X-direction) may be a bitline extension region in which bitlines in the memory regions CR extend, and the second extension region EXTw adjacent to the memory regions CR in the second direction (Y-direction) may be configured as a wordline extension region in which wordlines in the memory regions CR extend.

The memory regions CR may include a first memory region CR1, and a second memory region CR2 adjacent to the first memory region CR1 and spaced apart from the first memory region CR1 by the first extension region EXTb. Each of the peripheral circuit regions PC may include a sense amplifier array region SAR, a sub-wordline driver region SWDR, and a second peripheral region PER2 between the sense amplifier array region SAR and the sub-wordline driver region SWDR. The peripheral circuit regions PC may overlap the first and second memory regions CR1 and CR2, respectively.

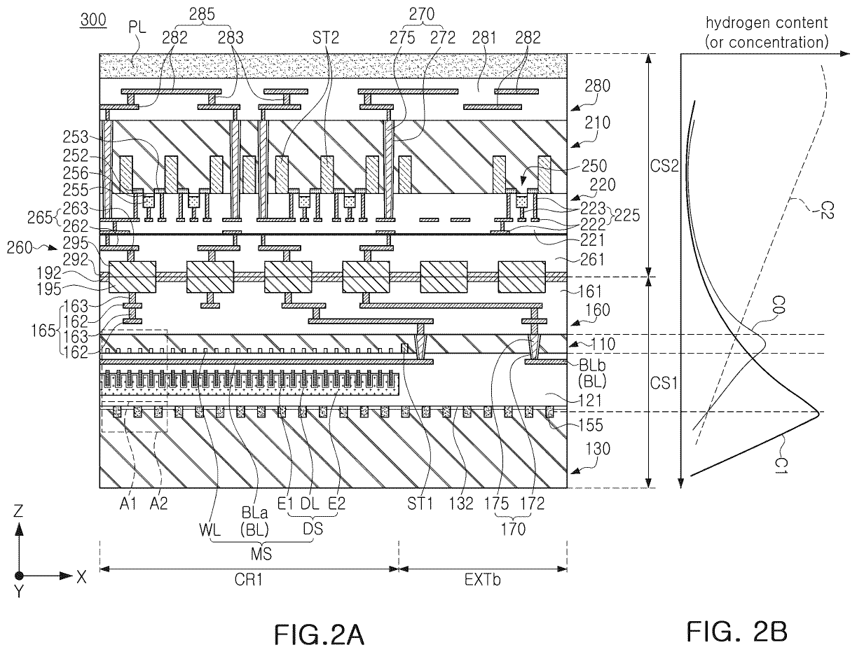

As such, the first chip structure CS1 may include a memory structure including first and second memory regions CR1 and CR2, and the second chip structure CS2 may include a peripheral circuit region PC having a sense amplifier array region SAR. The first chip structure CS1 and second chip structure CS2 may be electrically connected to each other by first and second bonding pads (195 and 295 in FIG. 2A).

FIG. 2A illustrates a cross-section of a portion of the bank BA of the semiconductor device 300 illustrated in FIG. 1B.

Referring to FIG. 2A, the semiconductor device 300 may include a first chip structure CS1 and a second chip structure CS2 stacked in order. Here, as described above, the first chip structure CS1 may include the first peripheral region PER1, the first memory region CR1, the second memory region CR2, and the first extension region EXTb between the first and second memory regions CR1 and CR2. However, in FIG. 2A, only the first memory region CRI and the first extension region EXTb are illustrated for ease of description.

The first chip structure CS1 may include a base substrate 130, a memory structure MS on the base substrate 130, a first substrate 110 on the memory structure MS, and a first wiring structure 160 (sometimes referred to as a first lower wiring structure) on the first substrate 110.

In some implementations, the first chip structure CS1 further includes first through-vias 170 penetrating the first substrate 110 and electrically connected to the memory structure MS. The first wiring structure 160 may include a first insulating layer 161 (sometimes referred to as a first lower insulating layer) and a first wiring layer 165 (sometimes referred to as a first lower wiring layer) disposed in the first insulating layer 161. The first wiring layer 165 may be electrically connected to the memory structure MS through the first through-vias 170. Each of the first through-vias 170 may include a first conductive plug 175 and a first insulating liner 172 surrounding the first conductive plug 175 to be electrically insulated from the first substrate 110. The first wiring layer 165 may include a plurality of first wiring pattern 162 disposed on different levels in the first insulating layer 161 and a first wiring via 163 connected to the plurality of first wiring pattern 162.

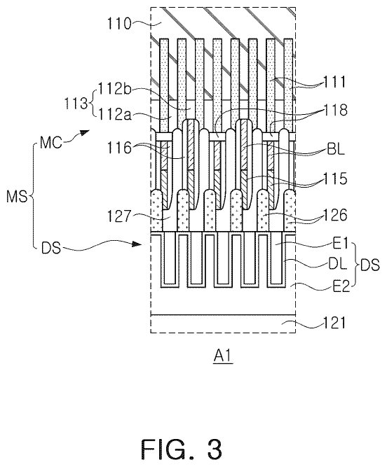

FIG. 3 is an enlarged diagram illustrating portion “Al” of the semiconductor device in FIG. 2A.

Referring to FIG. 3 along with FIG. 2, a memory structure MS may include a memory cell structure MC, a data storage structure DS, wordlines ML, and bitlines BL. In some implementations, the memory cell structure MC and the data storage structure DS may be disposed in order from an upper surface of the base substrate 130.

The data storage structure DS may include first electrodes E1, a second electrode E2 covering the first electrodes E1, and a dielectric layer DL between the first electrodes E1 and the second electrode E2. The data storage structure DS may be configured as memory cell capacitors for storing data. The memory structure MS may be disposed in a first memory region CR1, and also in a second memory region CR2. The bitlines BL may include a first bitline BLa of the first memory region CR1 and a second bitline BLb of the second memory region CR2.

The memory cell structure MC may include cell active regions 113 defined by a cell device isolation region 111, and cell transistors on the cell active regions 113. Each of the cell transistors may be configured as a cell switching device and may include first and second source/drain regions 112a and 112b disposed in the cell active regions 113, and a cell gate structure on the cell active regions 113. A gate electrode of the cell gate structure may be provided as wordlines WL.

In some implementations, the first substrate 110 may include a first device isolation region ST1, and wordlines WL may be buried in the first substrate 110. The cell device isolation region 111 may be formed as a shallow trench isolation. The cell device isolation region 111 may be formed simultaneously with the first device isolation region ST1. For example, the cell device isolation region 111 may include an insulating material such as silicon oxide and/or silicon nitride.

Referring to FIG. 3, the first chip structure CS1 may include a buffer insulating layer 118 on the cell active regions 113 and the cell device isolation region 111, bitlines BL on the buffer insulating layer 118, bitline capping layers 115 on the bitlines BL, cell contact structures 125 having pad portions extending to the bitlines capping layers 115 on both sides of the bitlines BL, an insulating isolation structure 126 disposed between the pad portions of the cell contact structures 125 and extending downwardly, and insulating spacers 116 on side surfaces of the bitlines BL and the bitlines capping layers 115. The bitlines BL may be electrically connected to the first source/drain regions 112a, and the cell contact structures 125 may be electrically connected to the second source/drain regions 112b.

As described above, a portion of the first lower wiring layer 165 may be electrically connected to the bitlines BL of the memory structure MS through the first through-vias 170. In the first memory region CR1, a portion of the first wiring layer 165 may be disposed on the data storage structure DS of the memory structure MS.

The first chip structure CS1 in some implementations may include a first bonding structure for connecting to the second chip structure CS2, and the first bonding structure may include a first bonding insulating layer 192 disposed on the first wiring structure 160, and first bonding pads 195 open to the first bonding insulating layer 192 and electrically connected to the first wiring layer 165. The first bonding pads 195 may be substantially coplanar with a surface of the first bonding insulating layer 192.

The second chip structure CS2 may include a second substrate 210, peripheral circuit transistors 250 disposed on a lower surface of the second substrate 210, a lower wiring structure 260 disposed on a lower surface of the second substrate 210, and an upper wiring structure 280 disposed on an upper surface of the second substrate 210.

The second substrate 210 may include a second device isolation region ST2 defining an active region in which the peripheral circuit transistors 250 are formed, and the peripheral circuit transistors 250 may include a gate electrode 255 on an active region, a gate dielectric layer 256 between the gate electrode 255 and the active region, and source/drains 252 and 253 in the active region on both sides of the gate electrode 255. For example, the peripheral circuit transistors 250 may include transistors vertically overlapping the memory structures MS of the first and second memory regions CRI and CR2, and transistors vertically overlapping the first peripheral circuit region PER1.

An intermediate wiring structure 220 may be disposed between the second substrate 210 and the lower wiring structure 260. The intermediate wiring structure 220 may include an intermediate insulating layer 221, and an intermediate wiring layer 225 disposed in the intermediate insulating layer 221 and connected to the peripheral circuit transistors 250. The intermediate wiring layer 225 may electrically connect the peripheral circuit transistors 250 on the second substrate 210 and may form a peripheral circuit. The intermediate wiring layer 225 may include conductive lines 222 and a contact via 223 connected to the conductive lines 222.

The lower wiring structure 260 may include a lower insulating layer 261 on the intermediate wiring structure 220, and a lower wiring layer 265 disposed on the lower insulating layer 261 and connected to the intermediate wiring layer 225. The lower wiring layer 265 may include a plurality of wiring pattern 262 disposed on different levels in the lower insulating layer 261, and a wiring via 263 connected to the plurality of wiring pattern 262.

In some implementations, the second chip structure CS2 may further include second through-vias 270 penetrating the second substrate 210 and electrically connected to the lower wiring layer 265. Each of the second through-vias 270 may include a conductive plug 275 and an insulating liner 272 surrounding the conductive plug 275 to be electrically insulated from the second substrate 210. The upper wiring structure 280 may include an upper insulating layer 281 and an upper wiring layer 285 disposed in the upper insulating layer 281. The upper wiring layer 285 may be electrically connected to the lower wiring layer 265 through the second through-vias 270. The upper wiring layer 285 may include a plurality of wiring pattern 282 disposed on different levels in the upper insulating layer 281, and a wiring via 283 connected to the plurality of wiring pattern 282. In some implementations, the input/output pad may be electrically connected to the upper wiring layer 285 and may be disposed to be exposed to an upper surface of the upper wiring structures 280.

The second chip structure CS2 may include a second bonding structure for connection to the first chip structure CS1, similarly to the first chip structure CS1, and the second bonding structure may include a second bonding insulating layer 292 disposed on the lower wiring structure 260, and second bonding pads 295 open to the second bonding insulating layer 292 and electrically connected to the lower wiring layer 265.

The first bonding pads 195 of the first chip structure CS1 and the second bonding pads 295 of the second chip structure CS2 may be bonded to each other. The first bonding pads 195 and the second bonding pads 295, directly bonded to each other, may be coupled to each other by mutual diffusion between metals (e.g., copper) through a high temperature annealing process. The metal included in the first bonding pads 195 and the second bonding pads 295 is not limited to copper, and may include other suitable metal materials (e.g., Au) which may be bonded to each other under similar conditions. By the bonding between the first bonding pads 195 and the second bonding pads 295, the first chip structure CS1 and the second chip structure CS2 may be firmly mechanically coupled and electrically connected to each other.

Also, in some implementations, the first bonding insulating layer 192 of the first chip structure CS1 and the second bonding insulating layer 292 of the second chip structure CS2 may be bonded to each other.

The first bonding insulating layer 192 and the second bonding insulating layer 292 may include the same dielectric material, for example, silicon oxide. In some implementations, the first bonding insulating layer 192 and the second bonding insulating layer 292 may include an insulating film formed of an insulating material different from that of the first insulating layer 161 and the lower insulating layer 261. For example, the other materials may include another insulating film such as SiCN, SiON or SiCO.

In some cases, in the process of manufacturing a semiconductor device (e.g., an oxidation process, plasma etching process, or the like), defects (e.g., dangling bonds) may occur in the memory cells. To reduce or prevent leakage current caused by the defects, a process of supplying hydrogen to the memory structure MS, especially the memory cell structure MC, may be necessary. By including a hydrogen-containing insulating layer 155, which may be a hydrogen source, in the semiconductor device 300 and diffusing hydrogen through an annealing process, hydrogen may be supplied to the memory cell structure MC.

However, hydrogen may have a detrimental effect on the peripheral circuit transistors 250 and various wiring layers (particularly, the upper wiring layer 285). For example, when a significant amount of hydrogen is supplied around the peripheral circuit transistors 250, hydrogen may react with halogen elements (e.g., chlorine) and acid may be produced, and acid may cause reliability issues in the peripheral circuit transistors 250, such as negative-bias temperature instability (NBTI) phenomenon.

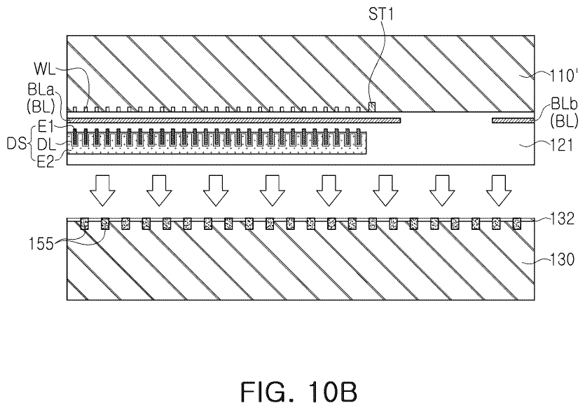

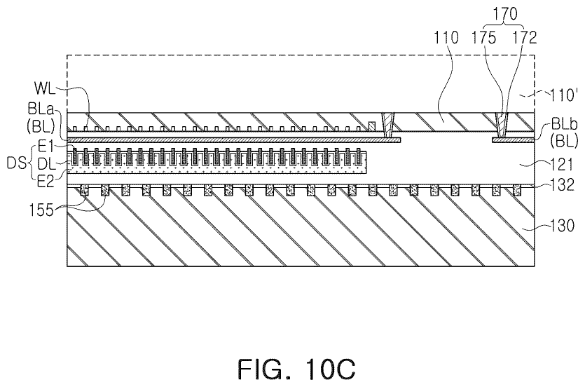

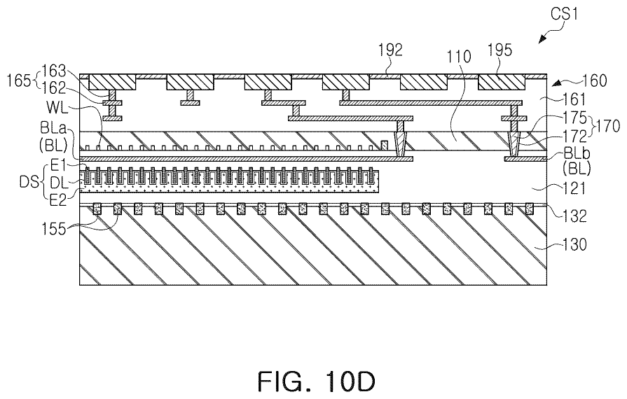

In some implementations, to increase positive effects while reducing or preventing the disadvantageous effects of supplying hydrogen, the time point at which the hydrogen-containing insulating layer 155 is included and/or a position of the hydrogen-containing insulating layer 155 may be changed. The semiconductor device 300 may include the hydrogen-containing insulating layer 155 disposed in a region close to the memory structure MS. The hydrogen-containing insulating layer 155 may be included in the process of manufacturing the lower chip structure CS1 (see FIGS. 10A to 10D). Adjusting the position of the hydrogen-containing insulating layer 155 to meet its purpose may calibrate the supply of sufficient hydrogen to the memory structure MS, the final target for hydrogen, while reducing disadvantageous effects on the other components. The adjustment of a position of the hydrogen-containing insulating layer 155 may be implemented in various manners.

For example, referring to FIG. 2A, the semiconductor device 300 further includes a hydrogen-containing insulating layer 155 on an upper surface of the base substrate 130 in contact with the memory structure MS. The hydrogen-containing insulating layer 155 may be configured as an insulating material containing hydrogen and/or deuterium at a relatively high enough concentration to supply hydrogen to surrounding components. For example, the hydrogen-containing insulating layer 155 may be silicon oxide containing hydrogen and/or deuterium. In some implementations, the hydrogen-containing insulating layer 155 may be silicon oxide deposited using oxygen (O₂) and silane (SiH₄) gas. For example, the hydrogen-containing insulating layer 155 may be an oxide formed by plasma-enhanced chemical vapor deposition (PECVD) or high-density plasma chemical vapor deposition (HDP-CVD).

In some implementations, the hydrogen-containing insulating layer 155 may be in direct contact with the interlayer insulating layer 121 disposed on the first substrate 110 and covering the memory structure MS. Since hydrogen diffused from the hydrogen-containing insulating layer 155 is disposed adjacent to the memory structure MS without passing through the other wiring structures 160, 260, 280 or the peripheral circuit transistor 250, hydrogen may be effectively supplied to the memory cell structure MC.

FIG. 2B is a graph of hydrogen content (or concentration) distribution according to a stacking direction of a semiconductor device in FIG. 2A.

Referring to FIG. 2B, “C0” may represent an ideal hydrogen content distribution suitable for curing defects in the memory structure MS. A hydrogen content may appear highest at a level of the memory cell structure MC.

“C1” may represent hydrogen content distribution by diffusion from the hydrogen-containing insulating layer 155 in the semiconductor device 300 as practically implemented. For example, the content of hydrogen in the semiconductor device 300 may be highest at a level of an upper surface of the base substrate 130, for example, the hydrogen-containing insulating layer 155, and may gradually decrease toward the second chip structure CS2 due to hydrogen diffusion.

“C2” may be a comparative example and may indicate hydrogen content distribution by diffusion under the same conditions (hydrogen concentration and annealing conditions of the hydrogen supply layer) as those of the diffusion of C1 when the passivation layer PL is used as a hydrogen supply layer. The content of hydrogen may be highest at an uppermost end of the semiconductor device 300, and may gradually decrease toward the base substrate 130 due to hydrogen diffusion.

As for the hydrogen content distribution of C1, in some implementations, the hydrogen-containing insulating layer may be disposed closer to the memory cell structure MC than in the example of C2. Accordingly, the content of hydrogen of C1 may be closer to the content of hydrogen of C0 than the content of hydrogen of C2 at the level of the memory cell structure MC.

Also, referring to C2, relatively high hydrogen content distribution may be exhibited in several wiring layers (particularly, the upper wiring layer 285) and the peripheral circuit transistors 250, whereas referring to C1, relatively low hydrogen content distribution may be exhibited in the upper wiring layer 285 and the peripheral circuit transistors 250. In some implementations, before the process of bonding with the second chip structure CS2 (e.g., after the process of bonding the memory structure MS to the base substrate 130 (see FIG. 10B)), by performing an annealing process for hydrogen diffusion, hydrogen may be prevented from diffusing into the second chip structure CS2.

As described above, by maintaining a relatively low hydrogen content in the components which may be adversely affected by diffusion or by fundamentally preventing diffusion, reliability of the semiconductor device 300 may be improved.

The hydrogen-containing insulating layer 155 may include insulating patterns buried in a plurality of trenches formed on an upper surface of the base substrate 130. The insulating patterns may be implemented in various structures and arrangements.

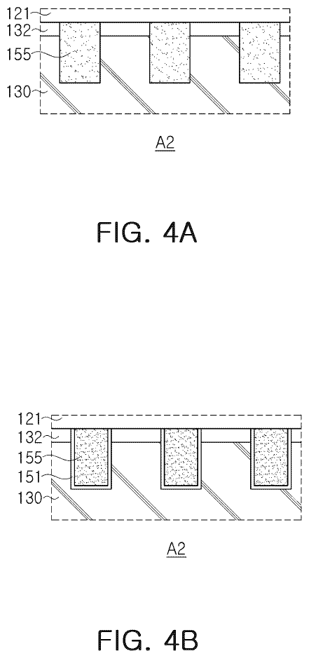

FIGS. 4A and 4B are enlarged diagrams illustrating various examples of portion “A2” of the semiconductor device in FIG. 2A.

Referring to FIG. 4A, insulating patterns of the hydrogen-containing insulating layer 155 may have upper surfaces substantially coplanar with an upper surface of the base substrate 130. A dielectric layer 132 having an upper surface substantially coplanar with upper surfaces of the insulating patterns may be disposed on an upper surface of the base substrate 130. The dielectric layer 132 on the base substrate 130 may be bonded to the interlayer insulating layer 121. The bonding may be implemented by bonding between dielectrics, similarly to bonding between the first bonding insulating layer 192 and the second bonding insulating layer 292 described above. The dielectric layer 132 and the interlayer insulating layer 121 may include the same dielectric material, for example, silicon oxide. For example, the dielectric layer 132 may be configured as a film in which a surface of the base substrate 130 is naturally oxidized. In some implementations, the dielectric layer 132 and the interlayer insulating layer 121 may instead or alternatively include other insulating films such as SiCN, SiON, or SiCO.

Referring to FIG. 4B, a barrier insulating film 151 may be further disposed between the hydrogen-containing insulating layer 155 and the base substrate 130. The barrier insulating film 151 may reduce or prevent diffusion of hydrogen in the hydrogen-containing insulating layer 155 to the base substrate 130. The barrier insulating film 151 may guide more hydrogen to diffuse in a desired direction, for example, toward the memory structure MS. For example, the barrier insulating film 151 may include silicon nitride, aluminum oxide, or aluminum nitride.

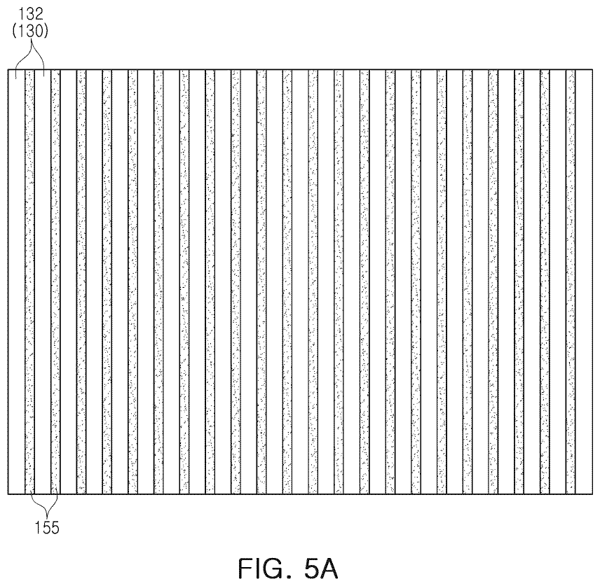

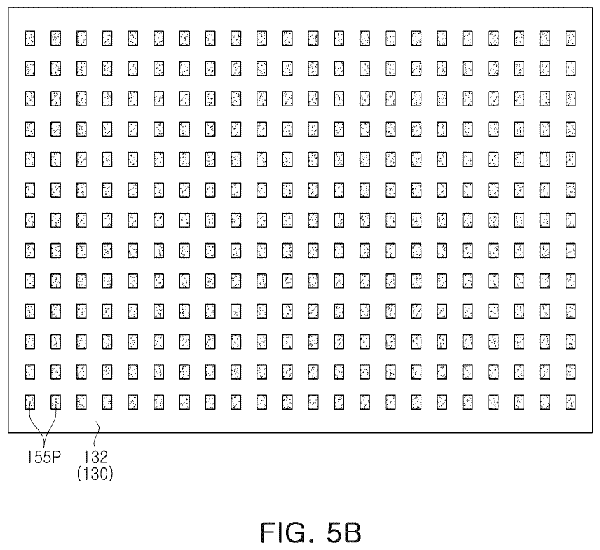

FIGS. 5A and 5B are plan diagrams illustrating a base substrate, illustrating various examples of a hydrogen-containing insulating layer 155 employed in the semiconductor device 300 in FIG. 2A.

Referring to FIG. 5A, each of the insulating patterns of the hydrogen-containing insulating layer 155 may have a line shape. Differently from the above example, referring to FIG. 5B, each of the insulating patterns 155P of the hydrogen-containing insulating layer 155 may have a quadrangular island structure. As described above, the insulating patterns may be formed in various shapes and arrangements and are not limited to those of FIGS. 5A-5B.

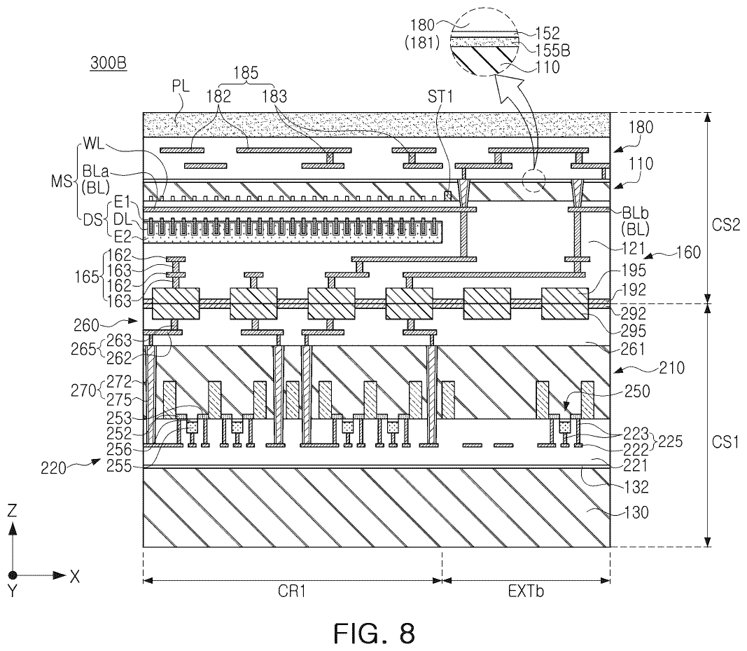

In some implementations, e.g., as shown in FIG. 8, the hydrogen-containing insulating layer 155 may be provided as a single-layer structure rather than a pattern (see FIG. 8A). In some implementations, the hydrogen-containing insulating layer 155 of the single-layer structure may also function as a bonding insulating layer for bonding with the interlayer insulating layer 121.

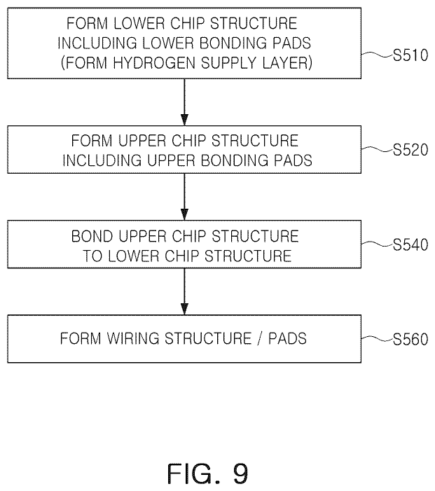

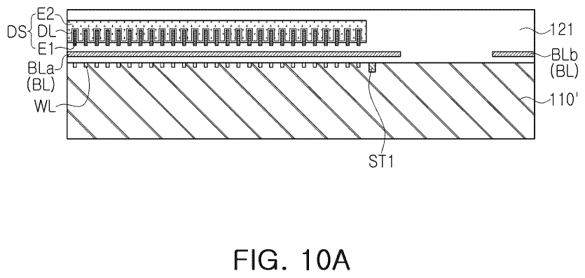

In some implementations, the employed hydrogen-containing insulating layer 155 may be included in the process of manufacturing the first chip structure CS1 (for example, see FIGS. 9 and 10A to 10D). Since the memory structure MS is formed on the first substrate 110 and is bonded to the base substrate 130, as illustrated in FIG. 2A, the memory structure MS may be disposed from an upper surface of the base substrate 130 in the order of the data storage structure DS and the memory cell structure MC

According to some implementations, by disposing the hydrogen-containing insulating layer 155 on an upper surface of the base substrate 130 adjacent to the memory structure MS, hydrogen may be stably supplied to the memory cell structure MC, thereby curing silicon defects (e.g., dangling bond) and improving electrical properties (e.g., leakage current reduction) of the semiconductor device 300. For example, when the semiconductor device 300 is configured as a DRAM device, a decrease in data retention time may be prevented or reduced. Also, by reducing hydrogen supplied to the upper wiring layer 285 and the peripheral circuit transistors 250, which may be adversely affected by hydrogen, reliability of the semiconductor device 300 may be improved.

In the aforementioned example, the hydrogen-containing insulating layer 155 is disposed on the upper surface of the base substrate 130 adjacent to the memory structure MS. However. other arrangements are also within the scope of this disclosure to dispose the hydrogen-containing insulating layer to reduce adverse impacts while improving hydrogen supply effectiveness.

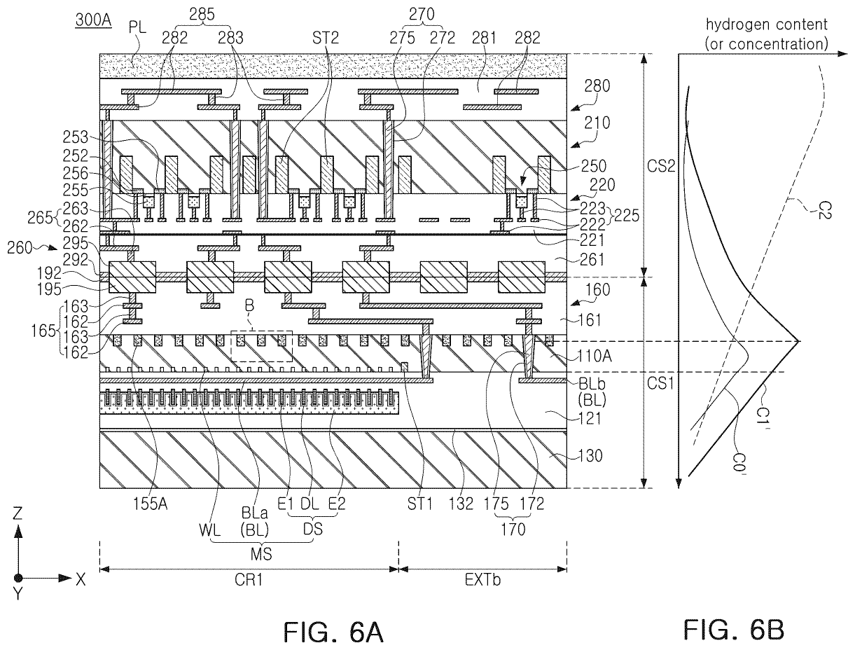

FIG. 6A is a cross-sectional diagram illustrating a semiconductor device according to some implementations.

Referring to FIG. 6A, a semiconductor device 300A may be similar to the example illustrated in FIGS. 1 to 5B, other than the configuration in which the hydrogen-containing insulating layer 155A is provided. Accordingly, the description of the example illustrated in FIGS. 1 to 5B may be applied to the example of FIG. 6A, unless otherwise indicated.

The first chip structure CS1 employed in some implementations may include a base substrate 130, a memory structure MS on the base substrate 130, a first substrate 110A on the memory structure MS, and a hydrogen-containing insulating layer 155A and a first wiring structure 160 disposed on the first substrate 110A. The hydrogen-containing insulating layer 155A may include insulating patterns buried in a plurality of trenches formed on an upper surface of the first substrate 110A.

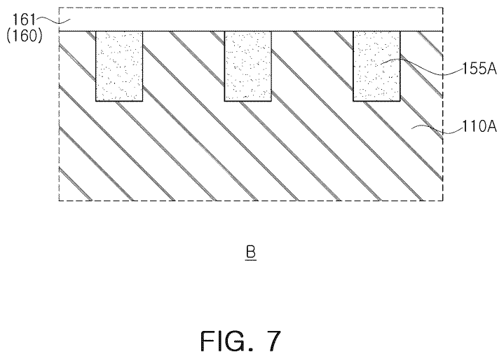

FIG. 7 is an enlarged diagram illustrating portion “B” of the semiconductor device in FIG. 6A.

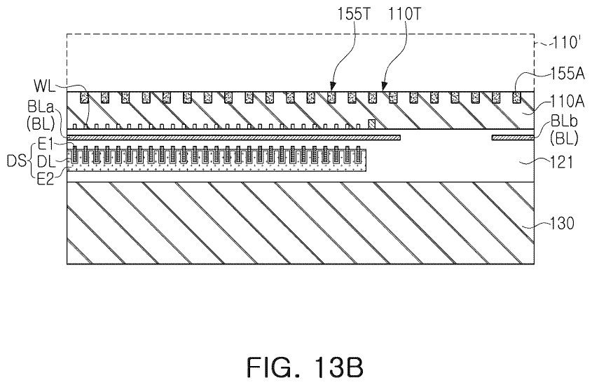

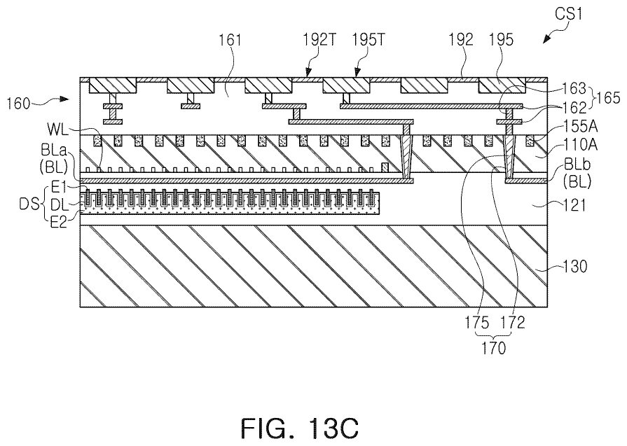

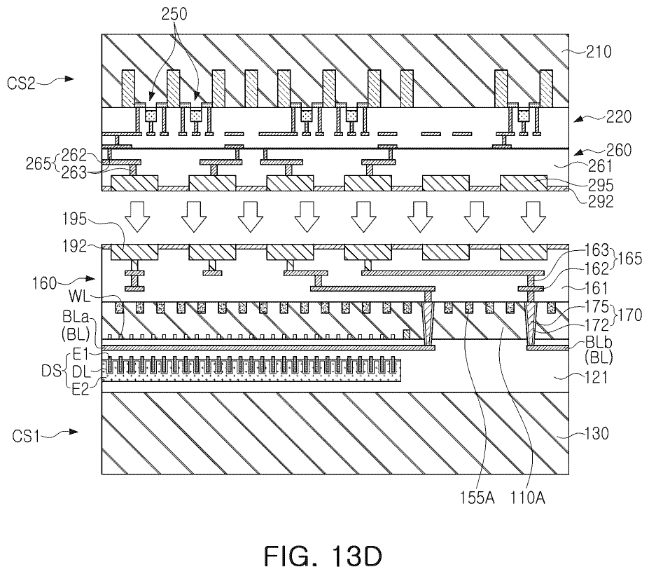

Referring to FIG. 7, insulating patterns of the hydrogen-containing insulating layer 155A may have an upper surface substantially coplanar with an upper surface of the first substrate 110A. After the memory structure MS is bonded to the base substrate 130, by applying a grinding process to the first substrate 110A, a thickness of the first substrate 110 may be reduced, and after the grinding process, the hydrogen-containing insulating layer 155A may be formed on an upper surface of the first substrate (see FIG. 13B). The first wiring structure 160 may be formed on an upper surface of the first substrate 110A on which the hydrogen-containing insulating layer 155A is formed (see FIG. 13C).

FIG. 6B is a graph of hydrogen content distribution according to a stacking direction of the semiconductor device in FIG. 6A.

Referring to FIG. 6B, hydrogen content distribution due to diffusion from the hydrogen-containing insulating layer 155 in the semiconductor device 300A is represented by “C1,” and “C2” is a comparative example described above representing hydrogen content distribution of an example in which a passivation layer PL is used as a hydrogen supply layer.

Specifically, a content of hydrogen in the semiconductor device 300A may be highest at a level of an upper surface of the first substrate 110A, and a significant amount of hydrogen may also diffuse into the memory structure MS disposed on an a lower r surface, which may be an active surface of the first substrate 110A. Accordingly, on a level of the memory cell structure MC, the content of hydrogen of C1′ may be similar to the content of hydrogen of C0′, e.g., more similar than to the content of hydrogen of C2.

Also, in wiring layers (particularly, the upper wiring layer 285) and the peripheral circuit transistors 250 in which disadvantageous effects from hydrogen may occur, C1 may have relatively lower hydrogen content distribution than C2. In some implementations, before the process of bonding with the second chip structure CS2 (e.g., before the process of forming the first wiring structure 160 (see FIG. 13C)), an annealing process for hydrogen diffusion may be performed, such that hydrogen may not diffuse into the second chip structure CS2.

Accordingly, reliability of the semiconductor device 300 may be improved by maintaining a low content of hydrogen or preventing diffusion in the wiring layers (for example, the upper wiring layer 285) and the peripheral circuit transistors 250.

FIG. 8 is a cross-sectional diagram illustrating a semiconductor device according to some

Referring to FIG. 8, a semiconductor device 300B may be configured similarly to that illustrated in FIGS. 1 to 5B, other than a configuration of a first chip structure CS1 (e.g., peripheral circuit transistors 250) and a second chip structure CS2 (e.g., a memory structure MS). In the semiconductor device 300B, the hydrogen-containing insulating layer 155B is disposed on the first substrate 110 in the second chip structure CS2, and the hydrogen-containing insulating layer 155B is provided as a single layer. Accordingly, the description of FIGS. 1 to 5B may be applied to the example of FIG. 8, unless otherwise indicated.

In the semiconductor device 300B, the first chip structure CS1 and the second chip structure CS12 may be configured differently from the semiconductor device 300. The first chip structure CS1 bonded to the base substrate 130 may include a second substrate 210 having peripheral circuit transistors 250, and the second chip structure CS2 on the first chip structure CS1 may include a first substrate 110 having a memory structure MS.

For example, the first chip structure CS1 may include a base substrate 130, a second substrate 210 having a lower surface opposing and upper surface of the base substrate 130, peripheral circuit transistors 250 disposed on a lower surface of the second substrate 210, a second lower wiring structure 220 disposed between the upper surface of the base substrate 130 and the lower surface of the second substrate 210, a second through-vias 270 penetrating the second substrate 210, and a second upper wiring structure 260 disposed on the upper surface of the second substrate 210.

The second lower wiring structure 220 may include a second lower wiring layer 225 electrically connected to the peripheral circuit transistors 250, and the second upper wiring structure 260 may include a second upper wiring structure 260 disposed on the upper surface of the second substrate 210.

The second chip structure CS2 may include a first substrate 110 having an upper surface including a hydrogen-containing insulating layer 155B disposed thereon, a memory structure MS disposed on a lower surface of the first substrate 110, a first lower wiring structure 160 disposed on a lower surface of the memory structure MS, a first through-vias 170 penetrating the first substrate 110, and a first upper wiring structure 180 disposed on the first substrate 110.

The first lower wiring structure 160 may have a first lower wiring layer 165 electrically connected to the memory structure MS, and the first upper wiring structure 180 may have a first upper wiring layer 185 electrically connected to the first lower wiring layer 165 through the first through-vias.

In some implementations, the first chip structure CS1 may include a second bonding insulating layer 292 disposed on the second upper wiring structure 260, and a second bonding pads 295 disposed on an upper surface of the second upper wiring structure 260 and electrically connected to the second upper wiring layer 265. Similarly, the second chip structure CS2 may include a first bonding insulating layer 192 disposed on a lower surface of the first lower wiring structure 160, and first bonding pads 195 disposed on a lower surface of the first lower wiring structure 160 and electrically connected to the first lower wiring layer 165.

The second bonding pads 295 of the first chip structure CS1 and the first bonding pads 195 of the second chip structure CS2 may be bonded to each other. The second bonding pads 295 and the first bonding pads 195, directly bonded to each other, may be coupled to each other by mutual diffusion between metals (e.g., copper) through a high temperature annealing process. Through the bonding between the second bonding pads 295 and the first bonding pads 195, solid mechanical coupling between the second chip structure CS2 and the first chip structure CS1, and electrical connection between the second chip structure CS2 and the first chip structure CS1 may be implemented. Also, the second bonding insulating layer 292 of the first chip structure CS1 and the first bonding insulating layer 192 of the second chip structure CS2 may be bonded to each other.

The hydrogen-containing insulating layer 155B in the example of FIG. 8 may be formed as a complete layer, e.g., rather than a pattern as described with respect to the devices 300, 300A. A barrier insulating film 152 may be disposed between the hydrogen-containing insulating layer 155B and the first upper wiring structure 180. The barrier insulating film 152 may prevent diffusion of hydrogen toward the first upper wiring structure 180. The first through-via 170 may penetrate the hydrogen-containing insulating layer 155B and the barrier insulating film 152 together with the first substrate 110.

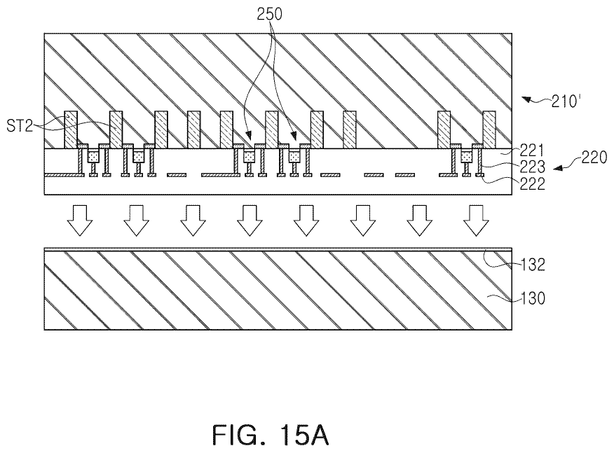

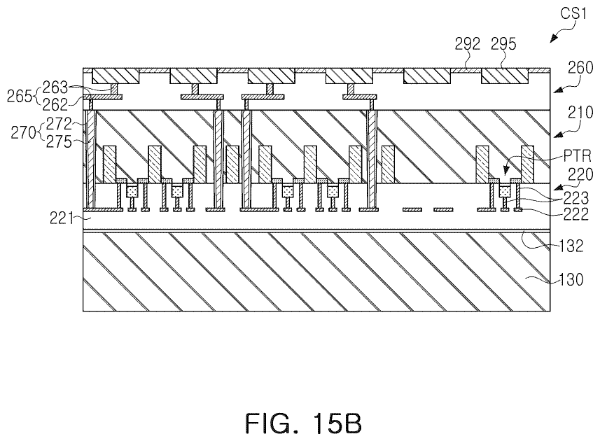

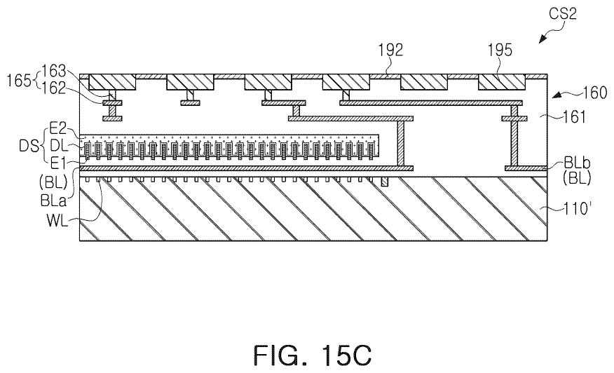

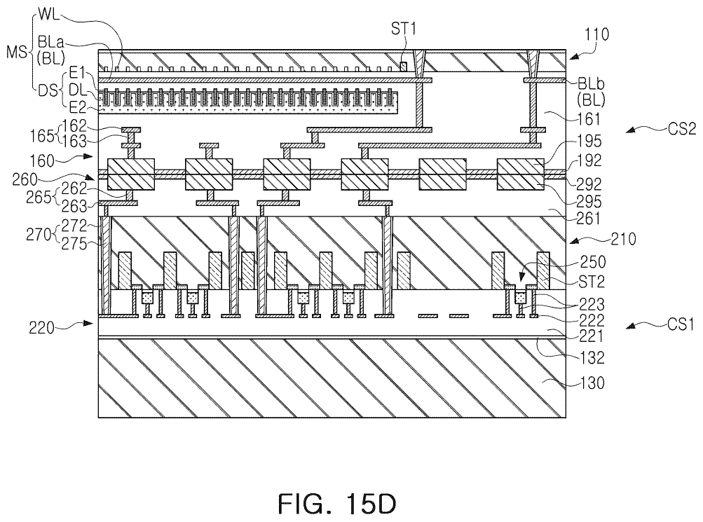

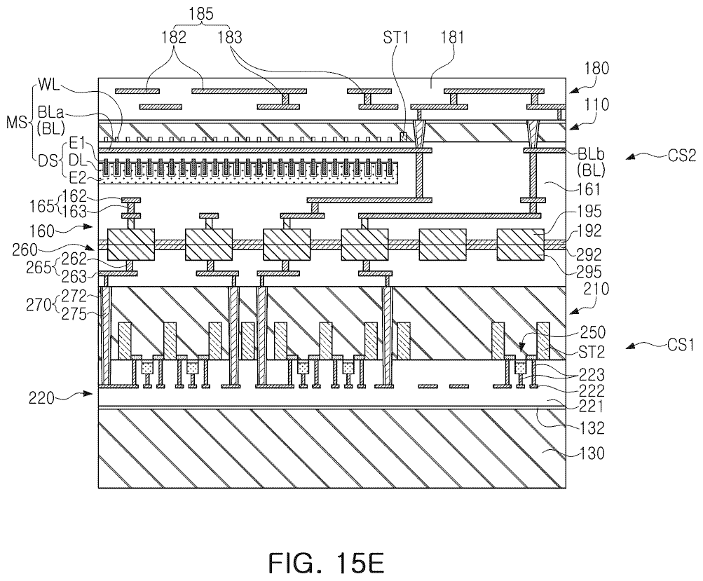

In some implementations, after the process of forming the first upper wiring structure 180 on the first substrate 110 (see FIG. 15E), an annealing process for hydrogen diffusion may be performed, thereby reducing or preventing hydrogen from diffusing to the first upper wiring layer 185.

Accordingly, reliability of the semiconductor device 300B may be improved by maintaining a low hydrogen content in components which may be adversely affected by diffusion or by preventing diffusion.

FIG. 9 is a flowchart illustrating a method of manufacturing a semiconductor device according to some implementations.

Referring to FIG. 9, in process (S510), a lower chip structure (also referred to as first chip structure) including lower bonding pads may be formed, and in a process of forming a lower chip structure, a hydrogen-containing insulating layer may be included. The hydrogen-containing insulating layer may be formed on a base substrate to which the memory structure is bonded (see FIGS. 10A to 10D), or may be formed on a first substrate of the memory structure bonded to the base substrate (see FIGS. 13A to 13D).

By forming an upper chip structure (also referred to as a second chip structure) including upper bonding pads (S520) and bonding the upper bonding pads and the lower bonding pads, the upper chip structure may be disposed on the lower chip structure (S540).

Thereafter, a wiring structure (e.g., the second upper wiring structure 280 in FIGS. 2A and 6A) may be formed (S560), and external connection pads may be further formed on the wiring structure.

Based on this process, hydrogen may be supplied to effectively cure memory cell defects by forming a hydrogen-containing insulating layer in a region adjacent to the memory structure in the lower chip structure. Also, before bonding with an upper chip structure including peripheral circuit transistors, an annealing process for hydrogen diffusion may be performed, thereby preventing hydrogen from diffusing into the upper chip structure.

As illustrated in FIG. 2A, the hydrogen-containing insulating layer 155 may be disposed on an upper surface of the base substrate 130 in contact with the memory structure MS in the first chip structure CS1. The method of manufacturing the semiconductor device 300 is described with reference to FIGS. 10A to 10D, 11A and 11B, and 12A to 12C.

FIGS. 10A to 10D are cross-sectional diagrams illustrating a process of manufacturing a lower chip structure, e.g., corresponding to process S510.

Referring to FIG. 10A, a memory structure MS may be formed on the first substrate 110′.

The memory structure MS may be configured as a DRAM memory. The memory structure MS may include a memory cell structure (“MC” in FIG. 3), a data storage structure DS, wordlines ML, and bitlines BL. A memory cell structure may be formed in an active region defined as a first device isolation region ST1 on the first substrate 110′, and a data storage structure DS may be formed on the memory cell structure.

The wordlines WL may be connected to a cell gate electrode of the memory cell, the bitlines BL may be electrically connected to the first source/drain regions of the memory cell, and the cell contact structures may be electrically connected to the second source/drain regions of the memory cell (see FIG. 3).

Thereafter, referring to FIG. 10B, a base substrate 130 having an upper surface on which a hydrogen-containing insulating layer 155 is disposed may be prepared, and the memory structure MS together with the first substrate 110′ may be bonded to an upper surface of the base substrate 130.

In some implementations, a trench may be formed on an upper surface of the base substrate 130, a hydrogen-containing insulating material may be deposited, and a planarization process such as CMP may be performed, thereby forming a hydrogen-containing insulating layer 155 including an insulating pattern. Before forming the hydrogen-containing insulating layer 155, a dielectric layer 132 for bonding with the memory structure MS may be formed on the base substrate 130. In some implementations, the dielectric layer 132 (e.g., silicon oxide) may be formed by natural oxidation without an additional deposition process. Also, primary bonding may be implemented by bonding between dielectrics. For example, the memory structure MS formed on the first substrate 110′ may be disposed on the base substrate 130 by bonding between the interlayer insulating layer 121 and the dielectric layer 132.

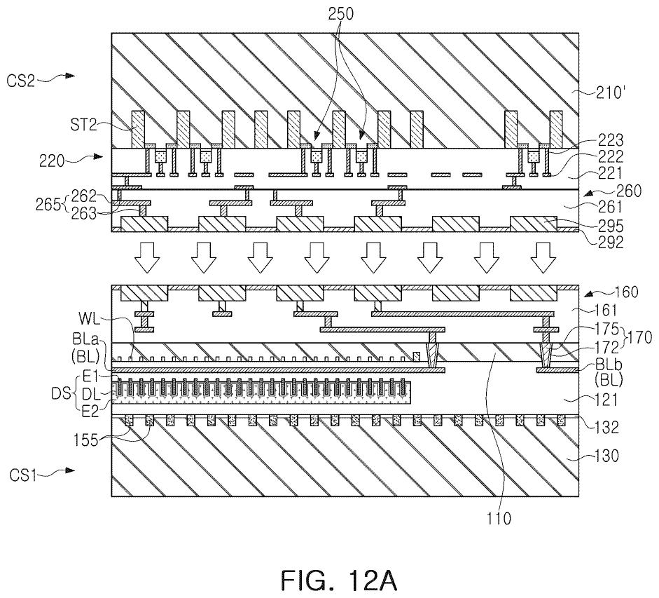

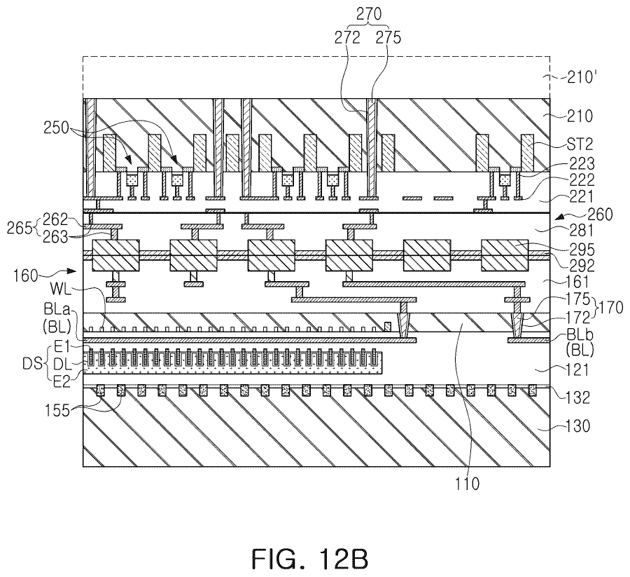

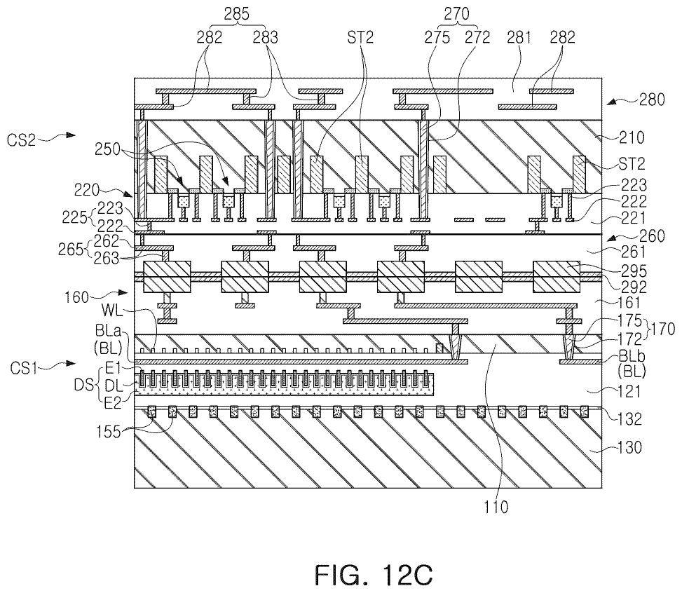

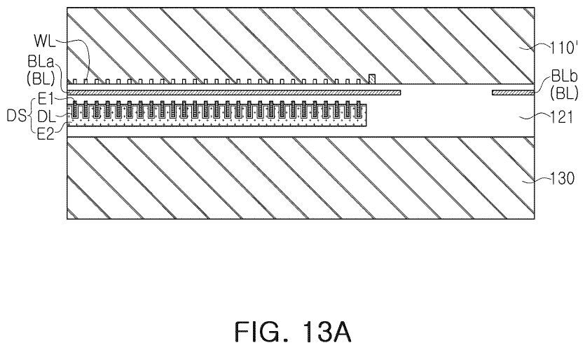

After the bonding process, an annealing process for diffusing hydrogen from the hydrogen-containing insulating layer 155 may be performed. Hydrogen may be diffused into the memory structure MS, especially the memory cell structure MC, and may cure defects (e.g., dangling bonding) in the memory cells, thereby reducing leakage current. In this process, by performing an annealing process for hydrogen diffusion (e.g., before the second chip structure CS2 is attached to the first chip structure CS1), hydrogen may be prevented from diffusing into the second chip structure CS2. The annealing process may be performed in another process before the process of bonding with the second chip structure CS2 (see FIG. 12A). For example, the annealing process may be performed after the grinding process (see FIG. 10C).

Referring to FIG. 10C, the first substrate 110′ (indicated by a dotted line) may be ground, and first through-vias 170 penetrating the first substrate 110 and electrically connected to the memory structure MS may be formed.

After the primary bonding, a thinning process of grinding the first substrate 110′ on which the memory structure MS is formed may be performed. The first through-vias 170 connected to the memory structure MS (e.g., the bitline BL) may be formed on the thin first substrate 110. The first through-vias 170 may be used as a path connecting the memory structure MS to the first wiring structure 160 to be formed in the subsequent process.

Thereafter, referring to FIG. 10D, a first wiring structure 160 may be formed on the first substrate 110, and a first bonding structure may be formed on the first wiring structure 160.

The first wiring structure 160 may include the first insulating layer 161 and the first wiring layer 165 in the first insulating layer 161. The first wiring layer 165 may be electrically connected to the first through-vias 170. The first bonding structure may include a first bonding insulating layer 192 disposed on the first wiring structure 160 and first bonding pads 195 buried in the first bonding insulating layer 192 and electrically connected to the first wiring layer 165. The surface 195T of the first bonding pads 195 may be substantially coplanar with a surface 192T of the first bonding insulating layer 192. For example, a metal included in the first bonding pads 195 is not limited to copper, and may include another metal material (e.g., Au) which may be bonded under similar conditions.

As such, in the process of forming the first chip structure CS1, the hydrogen-containing insulating layer 155 may be formed adjacent to the memory structure MS, and before bonding with the second chip structure CS2, by diffusing hydrogen the hydrogen-containing insulating layer 155, such that hydrogen is supplied to the memory cell through an annealing process, and an effective curing process may be performed.

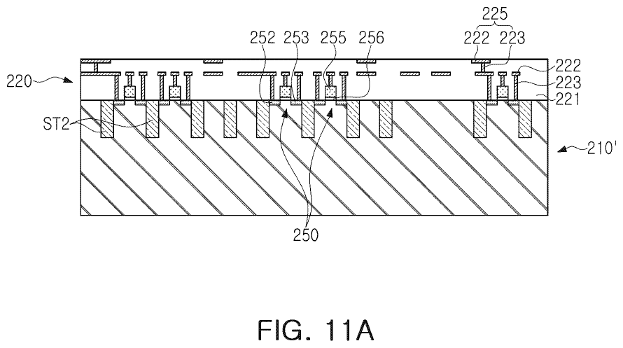

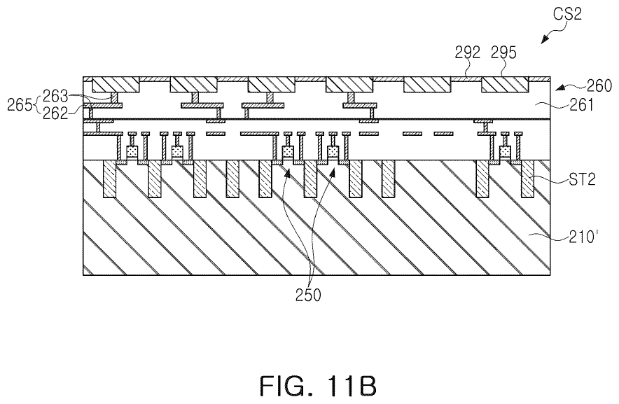

FIGS. 11A and 11B are cross-sectional diagrams illustrating a process of manufacturing an upper chip structure according to some implementations, e.g., corresponding to process S520.

Referring to FIG. 11A, peripheral circuit transistors 250 and an intermediate wiring structure 220 may be formed on a second substrate 210′. The intermediate wiring structure 220 may have an intermediate wiring layer 225 electrically connected to the peripheral circuit transistors 250. The intermediate wiring layer 225 may include contact vias 223 connected to the gate electrode 255 and the source/drains 252 and 253, and conductive lines 222 connecting the components.

Thereafter, referring to FIG. 11B, a lower wiring structure 260 may be formed on the intermediate wiring structure 220, and a second bonding structure may be formed on an upper surface of the lower wiring structure 260.

The lower wiring structure 260 may include a lower insulating layer 261 on the intermediate wiring structure 220, and a lower wiring layer 265 disposed in the lower insulating layer 261 and connected to the intermediate wiring layer 225. The lower wiring layer 265 may include a plurality of lower wiring pattern 262 disposed on different levels in the lower insulating layer 261, and a lower wiring via 263 connected to the plurality of lower wiring pattern 262. The second bonding structure may include a second bonding insulating layer 292 disposed on the lower wiring structure 260, and second bonding pads 295 buried in the second bonding insulating layer 292 and electrically connected to the lower wiring layer 265. The second bonding pads 295 may be substantially coplanar with a surface of the second bonding insulating layer 292. Similarly to the first bonding pads 195, a metal included in the second bonding pads 295 is not limited to copper and may include other metal materials (e.g., Au) which may be bonded under similar conditions.

Thereafter, a process of bonding the first chip structure CS1 to the second chip structure CS2 may be performed. FIGS. 12A to 12C are cross-sectional diagrams illustrating a bonding process according to some implementations, e.g., corresponding to process S540.

Referring to FIG. 12A, an upper surface of the lower wiring structure 260 may be bonded (in a secondary bonding process) to an upper surface of the first wiring structure 160 by bonding the second bonding pads 295 to the first bonding pads 195. Accordingly, the first chip structure CS1 and the second chip structure CS2 may be bonded to each other.

In this process, the first bonding pads 195 of the first chip structure CS1 and the second bonding pads 295 of the second chip structure CS2 may be bonded to each other. The first bonding pads 195 and the second bonding pads 295, directly bonded to each other, may be coupled to each other by mutual diffusion between metals (e.g., copper) through a high temperature annealing process. Through the bonding between the first bonding pads 195 and the second bonding pads 295, solid mechanical coupling between the first chip structure CS1 and the second chip structure CS2, and also electrical connection between the first chip structure CS1 and the second chip structure CS2 may be implemented. Also, the first bonding insulating layer 192 of the first chip structure CS1 and the second bonding insulating layer 292 of the second chip structure CS2 may be bonded to each other.

Thereafter, referring to FIG. 12B, the second substrate 210′ may be ground, and second through-vias 270 may be formed on the ground second substrate 210.

After secondary bonding, a thinning process may be performed by grinding the second substrate 210′ on which the peripheral circuit transistors 250 are formed. The second through-vias 270 connected to the intermediate wiring layer 225 or the lower wiring layer 265 may be formed on the ground second substrate 210. The second through-vias 270 may be used as a path connecting the lower wiring layer 265 to the upper wiring layer 285 to be formed in the subsequent process.

Thereafter, referring to FIG. 12C, an upper wiring structure 280 may be formed on the second substrate 210.

The upper wiring structure 280 may include an upper insulating layer 281 and an upper wiring layer 285 in the upper insulating layer 281. The upper wiring layer 285 may be electrically connected to the second through-vias 270 and accordingly, the upper wiring layer 285 may be electrically connected to the lower wiring layer 265 disposed below the second substrate 210.

As discussed above with respect to FIG. 6A, in some implementations, a hydrogen-containing insulating layer 155A may be provided to the first substrate 110 on which the memory structure MS is formed in the first chip structure CS1. An example of a method of manufacturing the semiconductor device 300A of FIG. 6A is described with reference to FIGS. 13A to 13D.

Referring to FIG. 13A, a memory structure MS may be formed on the first substrate 110′, and the memory structure MS may be bonded to an upper surface of the base substrate 130 along with the first substrate 110. The processes may be performed similarly to the processes described in FIGS. 10A and 10B. However, in this case, a hydrogen-containing insulating layer may not be disposed on an upper surface of the base substrate 130.

Thereafter, referring to FIG. 13B, the first substrate 110′ may be ground, and a hydrogen-containing insulating layer 155A may be formed on an upper surface of the ground first substrate 110.

After performing the grinding process, a trench 155T may be formed on an upper surface 110T of the first substrate 110A, and a hydrogen-containing insulating material may be deposited. Thereafter, a planarization process such as CMP may be performed to expose an upper surface of the first substrate 110A again, thereby forming a hydrogen-containing insulating layer 155A including an insulating pattern.

Thereafter, an annealing process for diffusing hydrogen from the hydrogen-containing insulating layer 155A may be performed. Hydrogen may diffuse to the memory structure MS, especially the memory cell structure MC, and may cure defects in the memory cells, thereby reducing leakage current. By performing an annealing process for hydrogen diffusion in this process (e.g., before attachment to the second chip structure CS2), hydrogen may be prevented from diffusing into the second chip structure CS2. The annealing process may be performed in another process before the process of bonding with the second chip structure CS2 (see FIG. 13D).

Thereafter, referring to FIG. 13C, similarly to the description provided for FIG. 10D, first through-vias 170 electrically connected to the memory structure MS may be formed on the first substrate 110A (see a portion of processes in FIG. 10C). Thereafter, a first wiring structure 160 having a first wiring layer 165 electrically connected to the first through-vias 170 may be formed on the first substrate 110A, and a first bonding insulating layer 192 and a first bonding pads 195 may be formed on an upper surface of the first wiring structure 160. The first bonding pads 195 may be electrically connected to the first wiring layer 165 (see processes in FIG. 10D).

Thereafter, referring to FIG. 13D, a process of bonding the second chip structure CS2 manufactured through the process in FIGS. 11A and 11B to the first chip structure CS1 may be performed.

The first wiring structure 160 and the lower wiring structure 260 may be bonded to each other by bonding the second bonding pads 295 of the second chip structure CS2 to the first bonding pads 195 of the first chip structure CS1.

In this process, the first bonding pads 195 of the first chip structure CS1 and the second bonding pads 295 of the second chip structure CS2 may be bonded to each other. The first bonding pads 195 and the second bonding pads 295, directly bonded to each other, may be coupled to each other by mutual diffusion between metals (e.g., copper) through a high temperature annealing process. Also, the first bonding insulating layer 192 of the first chip structure CS1 and the second bonding insulating layer 292 of the second chip structure CS2 may be bonded to each other.

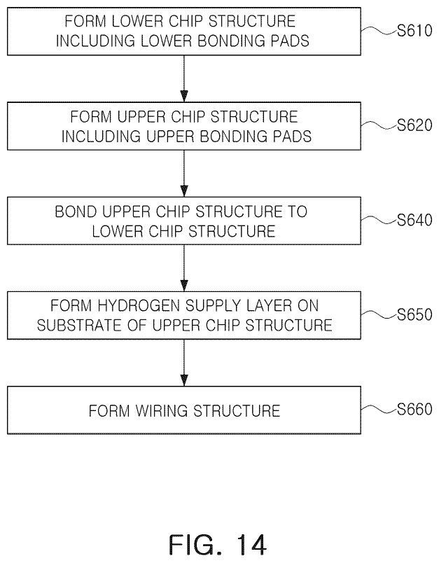

FIG. 14 is a flowchart illustrating a method of manufacturing a semiconductor device according to some implementations.

Referring to FIG. 14, similar to the process of FIG. 9, a lower chip structure (also referred to as ‘first chip structure’) including lower bonding pads may be formed (S610), and an upper chip structure (also referred to as ‘second chip structure’) including upper bonding pads may be formed (S620). Here, the lower chip structure may include peripheral circuit transistors, and the upper chip structure may include a memory structure including memory cells.

Thereafter, the upper chip structure may be disposed on the lower chip structure by bonding the upper bonding pads to the lower bonding pads (S640).

In this example, a hydrogen-containing insulating layer may be included before forming the wiring structure on a substrate of the upper chip structure (S650). Thereafter, a wiring structure (e.g., the first upper wiring structure 180 in FIG. 8) may be formed (S660), and external connection pads may be further formed on the wiring structure.

Accordingly, by forming a hydrogen-containing insulating layer in a region adjacent to the memory structure in the upper chip structure, hydrogen may be supplied to effectively cure defects in the memory cells. Also, before forming the wiring structure, by performing an annealing process for hydrogen diffusion, hydrogen may be prevented from diffusing into the wiring layer.

As illustrated in FIG. 8, in some implementations, a hydrogen-containing insulating layer 155B may be provided on the first substrate 110 of the second chip structure CS2 including the memory structure MS. The method of manufacturing of the semiconductor device 300B will be described with reference to FIGS. 15A to 15E, and is an example of the process of FIG. 14.

Referring to FIG. 15A, a second substrate 210′ on which the peripheral circuit transistors 250 and the intermediate wiring structure 220 are formed may be bonded to an upper surface of the base substrate 130. In this process, the second substrate 210′ on which the peripheral circuit transistors 250 are formed may be formed by a process similar to the process in FIG. 11A.

Coupling between the second substrate 210′ and the base substrate 130 may be implemented by bonding between the dielectric layer 132 on the base substrate 130 and the dielectric of the intermediate insulating layer 221. In some implementations, the dielectric layer 132 may be formed by natural oxidation without an additional deposition process.

Thereafter, referring to FIG. 15B, the second substrate 210′ may be ground, and second through-vias 270 penetrating the grinded second substrate 210 and electrically connected to the intermediate wiring structure 220 may be formed. Thereafter, a second upper wiring structure 260 having a second upper wiring layer 265 electrically connected to the second through-vias 270 may be formed on the second substrate 210. Also, a second bonding structure may be formed on an upper surface of the second upper wiring structure 260. The second bonding structure may include a second bonding insulating layer 292 disposed on the second upper wiring structure 260 and second bonding pads 295 buried in the second bonding insulating layer 292. The second bonding pads 295 may be electrically connected to the second upper wiring layer 265.

Thereafter, referring to FIG. 15C, a memory structure MS may be formed on the first substrate 110′ (e.g., similarly to the process in FIG. 10A). Thereafter, a first lower wiring structure 160 having a first lower wiring layer 165 electrically connected to the memory structure MS may be formed on the first substrate 110′, and, similarly to the process of FIG. 10D, a first bonding structure may be formed on the upper surface of the first lower wiring structure 160. The first bonding structure may include a first bonding insulating layer 192 disposed on the first lower wiring structure 160 and first bonding pads 195 buried in the first bonding insulating layer 192. The first bonding pads 195 may be electrically connected to the first lower wiring layer 165.

Thereafter, referring to FIG. 15D, the first lower wiring structure 160 may be bonded (in a secondary bonding process) to an upper surface of the second upper wiring structure 260 by bonding the first bonding pads 195 to the second bonding pads 295. After the secondary bonding process, the first substrate 110′ may be ground, and a hydrogen-containing insulating layer 155B (shown in FIG. 8) may be formed on the ground first substrate 110.

The hydrogen-containing insulating layer 155B may be provided on an upper surface of the first substrate 110, such that the hydrogen-containing insulating layer 155B may be disposed adjacent to the memory structure MS disposed on a lower surface of the first substrate 110. In some implementations, the hydrogen-containing insulating layer 155B is formed as a complete layer, e.g., rather than as, or in addition to, a plurality of insulating patterns. In some implementations, a barrier insulating film 152 may be disposed between the hydrogen-containing insulating layer 155B and the first upper wiring structure 180 (shown in FIG. 15E). The barrier insulating film 152 may prevent diffusion of hydrogen toward the first upper wiring structure 180. By performing an annealing process for hydrogen diffusion, hydrogen may be reduced or prevented from diffusing into the first upper wiring layer 185. Accordingly, a low hydrogen content may be maintained or diffusion may be prevented in components which may be adversely affected by diffusion.

Thereafter, referring to FIG. 15E, first through-vias 170 penetrating the first substrate 110 and electrically connected to the first lower wiring layer 165 may be formed, and a first upper wiring structure 180 having a first upper wiring layer 185 electrically connected to the first through-vias 170 on the first substrate 110 may be formed. The first through-via 170 may be formed to penetrate the hydrogen-containing insulating layer 155B and the barrier insulating film 152 together with the first substrate 110. Also, an input/output pad connected to the first upper wiring layer 185 may be formed on the first upper wiring structure 180.

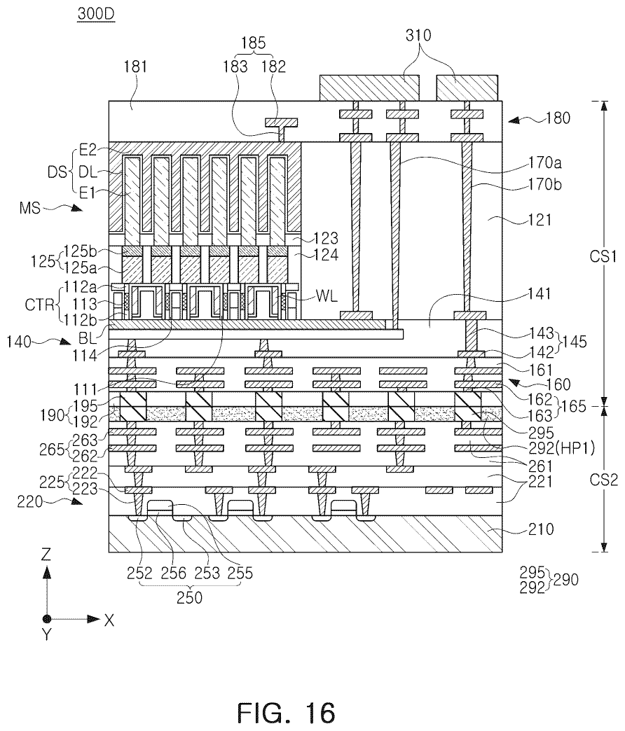

FIG. 16 is a cross-sectional diagram illustrating a semiconductor device according to some implementations.

Referring to FIG. 16, a semiconductor device 300D includes a second chip structure CS2 (or “lower chip structure”), and a first chip structure CS1 (also referred to as “upper chip structure”) stacked in the vertical direction (Z-direction) on the second chip structure CS2.

The first chip structure CS1 may include a memory structure MS, a cell routing wiring structure 140 electrically connected to the memory structure MS, and an interlayer insulating layer 121 covering the memory structure MS.

The memory structure MS may include bitlines BL, cell transistor CTR, and data storage structure DS. Bitlines BL may be electrically connected to a sense amplifier as described with respect to the semiconductor device 300. In some implementations, the data storage structure DS and the cell transistor CTR are disposed on the bitlines BL. The cell transistor CTR may be disposed between the bitlines BL and the data storage structure DS. The cell transistor CTR may be included in the memory cell region as described with respect to the semiconductor device 300. The cell transistor CTR may be configured as a vertical channel transistor and may include first and second source/drain regions 112a and 112b, a cell active region (in this example, a cell vertical channel region) 113, and wordlines WL (or gate electrodes). The first and second source/drain regions 112a and 112b may be disposed in an upper region of the cell transistor CTR. The first source/drain region 112a may be spaced apart from the second source/drain region 112b in the vertical direction (e.g., Z-direction). The first source/drain region 112a may be connected to the cell contact structure 125 disposed thereon, and the second source/drain region 112b may be connected to the bitline BL disposed therebelow.

In some implementations, wordlines WL (or gate electrodes) are disposed to face one side surface of the cell vertical channel region 113. For example, the wordlines WL may include doped polysilicon, metal, conductive nitride, metal-semiconductor compound, conductive oxide, conductive graphene, carbon nanotube, or combinations thereof. In some implementations, the wordlines WL includes a single-layer or multiple layers formed of the materials mentioned above.

The cell transistor CTR may include a gate dielectric layer 114 between the cell vertical channel region 113 and the wordlines WL. The gate dielectric layer 114 may include at least one of silicon oxide and a high-k dielectric. The high-k dielectric may have a dielectric constant higher than that of silicon oxide. The high-k dielectric may include metal oxide or metal oxynitride. For example, the high-k dielectric may include HfO₂, HfSiO, HfSiON, HfTaO, HfTiO, HfZrO, ZrO₂, Al₂O₃, or a combination thereof. In some implementations, the gate dielectric layer 114 is formed as a single layer or multiple layers formed of the materials described above.

The data storage structure DS may include first electrodes E1, a second electrode E2 on the first electrodes E1, and a dielectric layer DL between the first electrodes E1 and the second electrode E2. The data storage structure DS may be memory cell capacitors which may store data in a memory such as a DRAM.

In some implementations, the memory structure MS includes a cell contact structure 125 disposed between the cell transistor CTR and the data storage structure DS. In some implementations, the cell contact structure 125 penetrates the cell insulating layer 124 and may include a first cell contact layer 125a and a second cell contact layer 125b. The first cell contact layer 125a may be in contact with the cell transistor CTR and may be electrically connected to the second source/drain region 112b. For example, the first cell contact layer 125a may be formed as a silicon layer.

The first chip structure CS1 may further include an etch stop layer 123 covering the cell insulating layer 124 and the cell contact structure 125. The data storage structure DS may penetrate the etch stop layer 123 and may be electrically connected to the cell contact structure 125. The second cell contact layer 125b may be disposed below the first cell contact layer 125a and may be in contact with the data storage structure DS. As described above, the second cell contact layer 125b may be used as a landing pad for the data storage structure DS.

In some implementations, the cell routing wiring structure 140 includes a routing wiring layer 145 electrically connected to bitlines BL and an insulating layer 141 covering the routing wiring layer 145. The routing wiring layer 145 may include a wiring via 143 and a wiring pattern 142 connected to the wiring via 143. In some implementations, the cell routing wiring structure 140 includes a wiring layer including the first through-vias 170a disposed in the interlayer insulating layer 121.

In some implementations, the first chip structure CS1 may include a first upper wiring structure 180 disposed on the interlayer insulating layer 121 including the memory structure MS. The first upper wiring structure 180 may have a first upper insulating layer 181 and a first upper wiring layer 185 disposed in the first upper insulating layer 181. The first upper wiring layer 185 may be electrically connected to a bitline and/or a routing wiring layer 145 through first and second through-vias 170a and 170b. The first upper wiring layer 185 may include a plurality of wiring pattern 182 disposed on different levels in the first upper insulating layer 181, and a wiring via 183 connected to the plurality of wiring pattern 182. In some implementations, the input/output pad 310 is electrically connected to the first upper wiring layer 185 and may be formed on an upper surface of the first upper wiring structures 180.

In some implementations, the first chip structure CS1 may further include a first lower wiring structure 160 disposed on a lower surface of the cell routing wiring structure 140. The first wiring structure 160 may include a first wiring layer 165 connected to the routing wiring layer 145 and a first insulating layer 161 covering the first wiring layer 165. The first wiring layer 165 may include a plurality of wiring pattern 162 disposed on different levels in the first insulating layer 161, and a wiring via 163 connected to the plurality of wiring pattern 162. In some implementations, the first wiring layer 165 is electrically connected to the bitlines BL of the memory structure MS through a portion of the routing wiring layer 145. Also, the memory structure MS may be connected to the data storage structure DS through the second through-vias 170b connected to the first upper wiring layer 185 and the other portion of the routing wiring layer 145.

The first chip structure CS1 may include a bonding structure for connecting to the second chip structure CS2, and may include a first bonding insulating layer 192 disposed on a lower surface of the first lower wiring structure 160, and first bonding pads 195 open to the first bonding insulating layer 192 and electrically connected to the first lower wiring layer 165. The first bonding pads 195 may be substantially coplanar with a surface of the first bonding insulating layer 192.

The second chip structure CS2 of FIG. 16 may include a second substrate 210, peripheral circuit transistors 250 disposed on a lower surface of the second substrate 210, and a second wiring structure 260 disposed on an upper surface of the second substrate 210.

The second substrate 210 may include an active region in which peripheral circuit transistors 250 similar to those described with respect to the semiconductor device 300 are formed. The peripheral circuit transistors 250 may include a gate electrode 255 on an active region, a gate dielectric layer 256 between the gate electrode 255 and the active region, and source/drains 252 and 253 in an active region on both sides of the gate electrode 255. For example, the peripheral circuit transistors 250 may include transistors vertically overlapping the memory structures MS, and transistors vertically overlapping the peripheral circuit region.

An intermediate wiring structure 220 may be disposed between the second substrate 210 and the second wiring structure 260. The intermediate wiring structure 220 may include an intermediate insulating layer 221 and an intermediate wiring layer 225 disposed in the intermediate insulating layer 221 and connected to the peripheral circuit transistors 250. The intermediate wiring layer 225 may electrically connect the peripheral circuit transistors 250 on the second substrate 210 and may form a peripheral circuit. The intermediate wiring layer 225 may include conductive lines 222 and a contact via 223 connected to the conductive lines 222.

The second wiring structure 260 may be disposed on the second insulating layer 261 and the second insulating layer 261 on the intermediate wiring structure 220 and may include a second wiring layer 265 connected to the intermediate wiring layer 225. The second wiring layer 265 may include a plurality of wiring pattern 262 disposed on different levels in the second insulating layer 261 and a wiring via 263 connected to the plurality of wiring pattern 262.

The second chip structure CS2 may include a second bonding structure 290, similar to the first bonding structure of the first chip structure CS1. The second bonding structure may include a second bonding insulating layer 292 disposed on the second wiring structure 260, and second bonding pads 295 open to the second bonding insulating layer 292 and electrically connected to the second wiring layer 265.

The first bonding pads 195 of the first chip structure CS1 and the second bonding pads 295 of the second chip structure CS2 may be bonded to each other. The first bonding pads 195 and the second bonding pads 295, directly bonded to each other, may be coupled to each other by mutual diffusion between metals (e.g., copper) through a high temperature annealing process. The metal included in first bonding pads 195 and the second bonding pads 295 is not limited to copper, and may include other metal materials (e.g., Au) which may be bonded under similar conditions. Through the bonding between the first bonding pads 195 and second bonding pads 295, the first chip structure CS1 and the second chip structure CS2 may be firmly mechanically coupled and electrically connected to each other.

Also, the first bonding insulating layer 192 of the first chip structure CS1 and the second bonding insulating layer 292 of the second chip structure CS2 may be bonded to each other. The first bonding insulating layer 192 and the second bonding insulating layer 292 may include the same dielectric material, for example, silicon oxide. In some implementations, the first bonding insulating layer 192 and the second bonding insulating layer 292 include an insulating material different from those of the first lower insulating layer 161 and the second insulating layer 261, respectively, or may further include an insulating film of a different material. For example, the other materials may include other insulating films such as SiCN, SiON or SiCO.

In the some implementations, a portion of the insulating structure of the semiconductor device 300D may be provided as a hydrogen supply layer formed of a hydrogen-containing insulating material. The insulating structure as a hydrogen supply layer HP may be included in processes of manufacturing the first and second chip structures CS1 and CS2. Similarly to the hydrogen-containing insulating layers described above, by diffusing hydrogen through an annealing process before or after bonding the first and second chip structures CS1 and CS2, defects (e.g., dangling bonds) of the memory cells generated during the process (e.g., an oxidation process, a plasma etching process, or the like) of manufacturing the semiconductor device 300D may be addressed. By including the hydrogen-containing insulating layer 155, a hydrogen source, in the semiconductor device 300, and diffusing hydrogen through an annealing process, hydrogen may be supplied to the memory cell region MC.

In some implementations, at least one of the first and second bonding insulating layers 192 and 292 is provided as a hydrogen supply layer HP. As illustrated in FIG. 16, the second bonding insulating layer 292 (HP1) may be formed of an insulating material containing hydrogen and/or deuterium at a high enough concentration to supply hydrogen to surrounding components. For example, the second bonding insulating layer 292, which is the hydrogen supply layer HP1, may be silicon oxide containing hydrogen and/or deuterium. In some implementations, the second bonding insulating layer 292 may be silicon oxide deposited using oxygen (O₂) and silane (SiH₄) gas. For example, the second bonding insulating layer 292 may be deposited using plasma-enhanced chemical vapor deposition (PECVD), or may be an oxide formed by high-density plasma chemical vapor deposition (HDP-CVD). These descriptions can equally apply to the first bonding insulating layer 192 instead of, or in addition to, the second bonding insulating layer 292.

As described above, various different insulating structures may be selectively provided as a hydrogen-containing insulating layer in the process of manufacturing each of the first and second chip structures CS1 and CS2.

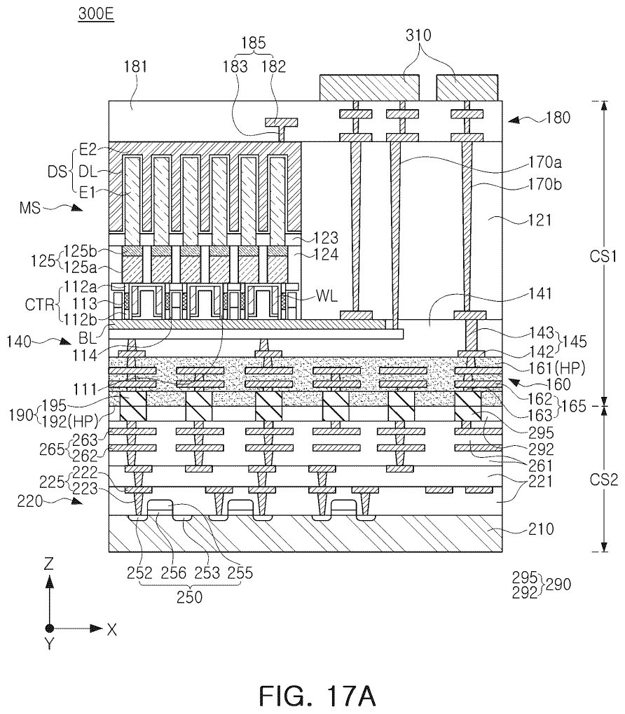

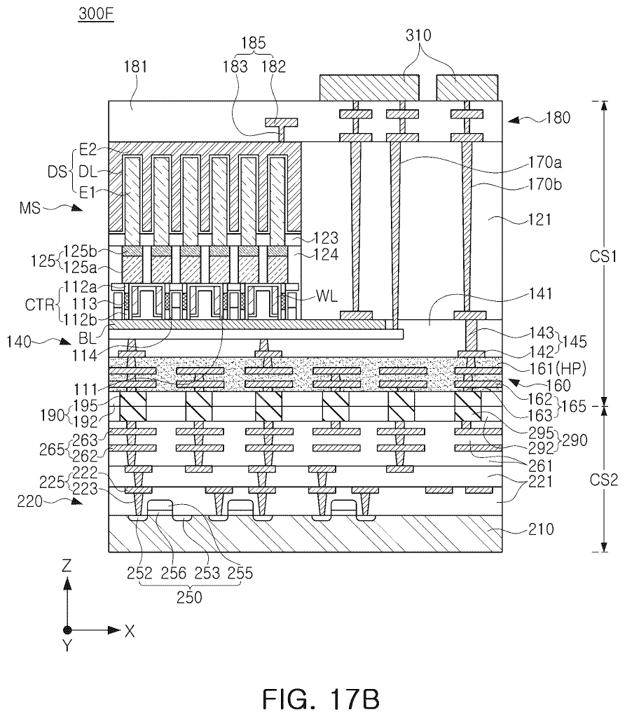

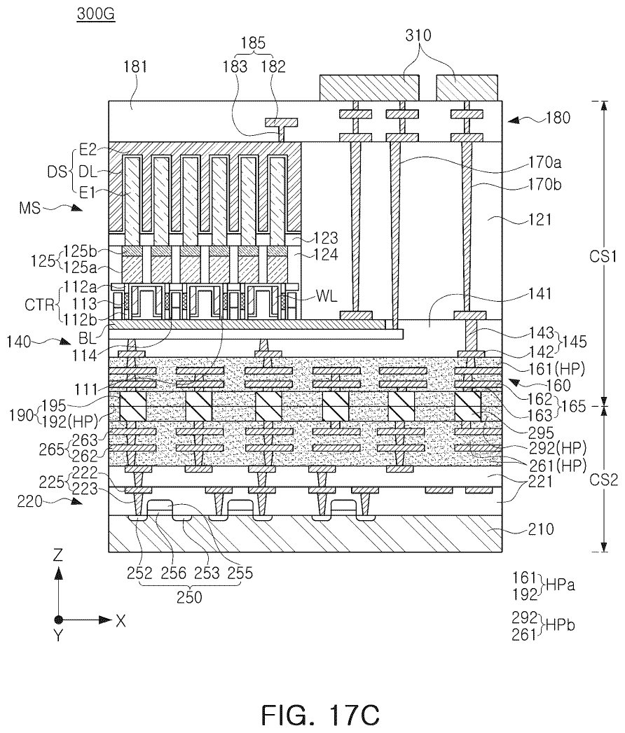

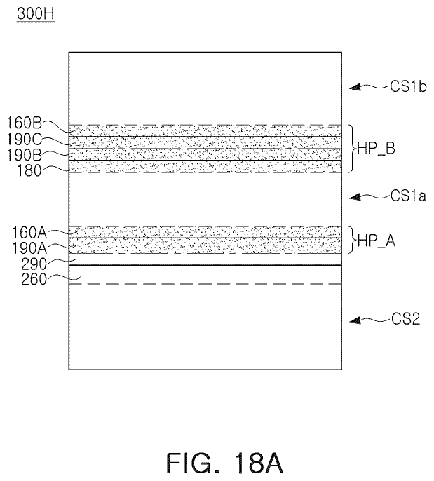

FIGS. 17A to 17C are cross-sectional diagrams illustrating a semiconductor device according to some implementations. Referring to FIG. 17A, a semiconductor device 300E may be similar to the structure described with respect to FIG. 16 (e.g., can have the same characteristics except where noted otherwise), and may have a configuration in which a plurality of insulating structures 161 and 192 of the first chip structure CS1 are provided as a hydrogen supply layer HP.

In the example of FIG. 17A, each of the first lower insulating layer 161 and the first bonding insulating layer 192 of the first chip structure CS1 may be provided as the hydrogen supply layer HP. The first lower insulating layer 161 and the first bonding insulating layer 192 may be formed of an insulating material containing hydrogen and/or deuterium, respectively. For example, the first lower insulating layer 161 and first bonding insulating layer 192, which are the hydrogen supply layer HP, may be silicon oxide containing hydrogen and/or deuterium. In the annealing process to address defects in the adjacent memory structure MS, hydrogen may be diffused into the memory structure MS from the first lower insulating layer 161 and the first bonding insulating layer 192. In some implementations, the annealing process may be performed in the process of manufacturing the first chip structure before bonding to the second chip structure

Referring to FIG. 17B, a semiconductor device 300F may be similar to the example illustrated in FIG. 16 (e.g., may have the same characteristics except where noted otherwise). The semiconductor device 300F has a configuration in which the first lower insulating layer 161 of the first chip structure CS1 is provided as the hydrogen supply layer HP.

For example, only the first lower insulating layer 161 of the first chip structure CS1 may be provided as the hydrogen supply layer HP. The first lower insulating layer 161 may include a plurality of insulating layers, each of which may be formed of an insulating material containing hydrogen and/or deuterium. For example, the first lower insulating layer 161, which is the hydrogen supply layer HP, may be silicon oxide containing hydrogen and/or deuterium. In the annealing process to address defects in the adjacent memory structure MS, hydrogen may be diffused into the memory structure MS from the first lower insulating layer 161.

Referring to FIG. 17C, Referring to FIG. 17C, a semiconductor device 300G may be similar to the example illustrated in FIG. 16 (e.g., may have the characteristics described with respect to FIG. 16 except where noted otherwise), and may have a configuration in which the insulating layers 161 and 192 of the first chip structure CS1 and also the insulating layers 261 and 292 of second chip structure CS2 are provided as hydrogen supply layer HP, respectively.

Each of the first lower insulating layer 161 and the first bonding insulating layer 192 of the first chip structure CS1, and the second insulating layer 261 and the second bonding insulating layer 292 of the second chip structure CS2, may be provided as a hydrogen supply layer HP. The first and second insulating layers 161 and 261 and the first and second bonding insulating layers 192 and 292 may be formed of an insulating material containing hydrogen and/or deuterium. For example, the hydrogen supply layers HP may be silicon oxide containing hydrogen and/or deuterium.

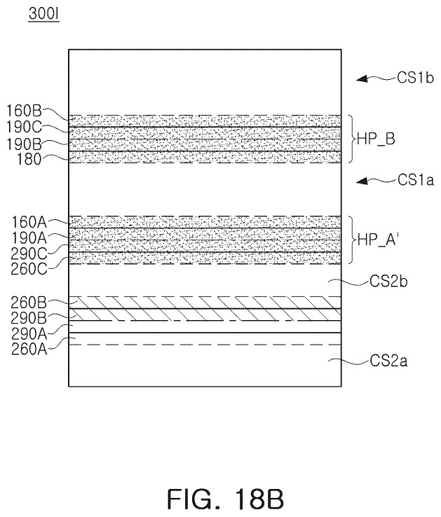

Various configurations and arrangements of the hydrogen supply layer are applicable to various semiconductor device structures. FIGS. 18A and 18B are views illustrating a semiconductor device according to some implementations.

Referring to FIG. 18A, a semiconductor device 300H include a second chip structure CS2 and two first chip structures CS1a and CS1b stacked in order on a second chip structure CS2.

The two first chip structures may be configured as the first lower chip structure CS1a and the first upper chip structure CS1b each having a memory structure (‘MS’ in FIG. 16), similarly to the first chip structure CS1 in FIG. 16. The bonding structures 190B and 190C may be formed on the first upper wiring structure 180 of the first lower chip structure CS1a and on the lower wiring structure 160B of the first upper chip structure CS1b, respectively. The first lower chip structure CS1a and the first upper chip structure CS1b may be electrically and mechanically connected to each other by the bonding structures 190B and 190C.

The second chip structure CS2 may include a peripheral circuit, similarly to the second chip structure CS2 in FIG. 16. The bonding structures 290 and 190A may be formed on the second wiring structure 260 of the second chip structure CS2 and on the lower wiring structure 160A of the first lower chip structure CS1a, respectively. The second chip structure CS2 and the first lower chip structure CS1a may be electrically and mechanically connected to each other by bonding structures 290 and 190A.

A Insulating structures of the semiconductor device 300H may be provided as a hydrogen supply layer. In some implementations, the insulating structure between the second chip structure CS2 and the first lower chip structure CS1a may be provided as a first hydrogen supply layer HP_A. The first hydrogen supply layer HP_A may include insulating layers of each of the lower wiring structure 160A and the bonding structure 190A of the first lower chip structure CS1a. Also, the insulating structure between the first lower chip structure CS1a and the first upper chip structure CS1b may be provided as a second hydrogen supply layer HP_B. The second hydrogen supply layer HP_B may include insulating layers of each of the first upper wiring structure 180 and the bonding structure 190B of the first lower chip structure CS1a, and insulating layers of each of the lower wiring structure 160B and the bonding structure 190C of the first upper chip structure CS1b.

Referring to FIG. 18B, a semiconductor device 300I according to some implementations may be configured similarly to the example of FIG. 18A (e.g., may have the same characteristics except where noted otherwise), and may have a configuration in which the second chip structure includes the second lower and the upper chip structures CS2a and CS2b, and the first hydrogen supply layer HP_A′ may be implemented differently.

Similar to the second chip structure CS2 in FIG. 16, the two second chip structures may be configured as a second lower chip structure CS2a and a second upper chip structure CS2b in which the peripheral circuit transistors are disposed separately. The bonding structures 290B and 290A may be formed on the lower wiring structure 260B of the second upper chip structure CS2b and on the upper wiring structure 260A of the second lower chip structure CS2a, respectively. Also, the second lower chip structure CS2a and the second upper chip structure CS2b may be electrically and mechanically connected to each other by bonding structures 290B and 290A.

Insulating structures of the semiconductor device 300I may be provided as a hydrogen supply layer. For example, similarly to the configuration of FIG. 18A, an insulating structure between the first lower chip structure CS1a and the first upper chip structure CS1b may be provided as a second hydrogen supply layer HP_B. The second hydrogen supply layer HP_B may include insulating layers of each of the first upper wiring structure 180 and the bonding structure 190B of the first lower chip structure CS1a, and insulating layers of each of the lower wiring structure 160B and the bonding structure 190C of the first upper chip structure CS1b.

An insulating structure between the second upper chip structure CS2b and the first lower chip structure CS1a may be provided as the first hydrogen supply layer HP_A′. The first hydrogen supply layer HP_A′ may include insulating layers of each of the lower wiring structure 160A and the bonding structure 190A of the first lower chip structure CS1a, and insulating layers of each of the upper wiring structure 260C and the bonding structure 290C of the second upper chip structure CS2b.

The insulating structure between the second upper chip structure CS2b and the second lower chip structure CS2a may not include any hydrogen supply layer. In some implementations, insulating layers of each of the lower wiring structure 260B and the bonding structure 290B of the second upper chip structure CS2b and insulating layers of each of the upper wiring structure 260A and the bonding structure 290A of the second lower chip structure CS2a may be provided as an insulating layer not intentionally containing hydrogen.

The configuration of including a hydrogen supply layer may be selectively applied to a desired insulating structure in a semiconductor device having various structures.

Accordingly, by stably supplying hydrogen by disposing the hydrogen-containing insulating layer for hydrogen supply adjacent to the defect generation region (e.g., the memory cell structure), electrical properties of the semiconductor device may be improved.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Further, while various examples have been illustrated and described above, it will be apparent to those skilled in the art that modifications and variations may be made without departing from the scope of this disclosure.

1. A semiconductor device, comprising:
a first chip structure; and
a second chip structure on the first chip structure,
wherein the first chip structure includes:
a base substrate,
a memory structure disposed on the base substrate,
a first substrate disposed on the memory structure,
first through-vias extending through the first substrate and electrically connected to the memory structure,
a first wiring structure disposed on the first substrate and including a first wiring layer electrically connected to the memory structure through the first through-vias,
first bonding pads disposed on an upper surface of the first wiring structure and
electrically connected to the first wiring layer, and
a hydrogen-containing insulating layer disposed in a region adjacent to the memory structure in the first chip structure, and
wherein the second chip structure includes:
a second substrate,
peripheral circuit transistors disposed on a lower surface of the second substrate,
a lower wiring structure disposed on the lower surface of the second substrate and including a lower wiring layer electrically connected to the peripheral circuit transistors;
second bonding pads disposed on a lower surface of the lower wiring structure and electrically connected to the lower wiring layer, the second bonding pads bonded to the first bonding pads,
second through-vias extending through the second substrate and electrically connected to the lower wiring layer, and
an upper wiring structure disposed on an upper surface of the second substrate and including an upper wiring layer electrically connected to the lower wiring layer through the second through-vias.

2. The semiconductor device of claim 1, wherein the hydrogen-containing insulating layer is disposed on an upper surface of the base substrate and is in contact with the memory structure.

3. The semiconductor device of claim 2, wherein the hydrogen-containing insulating layer includes insulating patterns provided at a plurality of trenches formed in the upper surface of the base substrate, and wherein the insulating patterns have an upper surface coplanar with the upper surface of the base substrate.

4. The semiconductor device of claim 2, wherein the hydrogen-containing insulating layer is disposed on the upper surface of the base substrate and has a flat upper surface.

5. The semiconductor device of claim 2, further comprising:
a barrier insulating film disposed between the hydrogen-containing insulating layer and the base substrate.

6. The semiconductor device of claim 1, wherein the hydrogen-containing insulating layer is disposed on an upper surface of the first substrate.

7. The semiconductor device of claim 6, wherein the hydrogen-containing insulating layer includes insulating patterns buried in a plurality of trenches formed in the upper surface of the first substrate, and wherein the insulating patterns have an upper surface coplanar with the upper surface of the first substrate.

8. The semiconductor device of claim 6, wherein the hydrogen-containing insulating layer is disposed on an entire region of the upper surface of the first substrate and has a flat surface.

9. The semiconductor device of claim 1, wherein the memory structure includes a data storage structure on an upper surface of the base substrate and a memory cell structure stacked on the data storage structure.

10. The semiconductor device of claim 1,
wherein the upper surface of the first wiring structure is coplanar with an upper surface of the first bonding pads, and wherein the lower surface of the lower wiring structure is coplanar with lower surfaces of the second bonding pads, and
wherein the upper surface of the first wiring structure is bonded to the lower surface of the lower wiring structure.

11. A semiconductor device, comprising:
a first chip structure; and
a second chip structure on the first chip structure,
wherein the first chip structure includes:
a base substrate having an upper surface on which a hydrogen-containing insulating layer is disposed,
a memory structure disposed on the base substrate and in contact with the hydrogen-containing insulating layer,
a first wiring structure disposed on the memory structure and including a first wiring layer electrically connected to the memory structure, and
first bonding pads disposed on an upper surface of the first wiring structure and electrically connected to the first wiring layer, and
wherein the second chip structure includes:
a second substrate,
peripheral circuit transistors disposed on a lower surface of the second substrate,
a lower wiring structure disposed on the lower surface of the second substrate, the lower wiring structure including a lower wiring layer electrically connected to the peripheral circuit transistors, wherein the lower wiring structure is bonded to the first wiring structure,
second bonding pads disposed on a lower surface of the lower wiring structure and electrically connected to the lower wiring layer, wherein the second bonding pads are bonded to the first bonding pads,
second through-vias extending through the second substrate and electrically connected to the lower wiring layer, and
an upper wiring structure disposed on an upper surface of the second substrate and including an upper wiring layer electrically connected to the lower wiring layer through the second through-vias.

12. The semiconductor device of claim 11, wherein the first chip structure includes:
a first substrate disposed between the memory structure and the first wiring structure; and
first through-vias extending through the first substrate and electrically connecting the memory structure to the first wiring layer.

13. The semiconductor device of claim 11, wherein the hydrogen-containing insulating layer includes insulating patterns provided at a plurality of trenches formed in the upper surface of the base substrate, and wherein the insulating patterns have an upper surface coplanar with the upper surface of the base substrate.

14. The semiconductor device of claim 13, further comprising:
a barrier insulating film disposed between the hydrogen-containing insulating layer and the base substrate.

15. A semiconductor device, comprising:
a second chip structure; and
a first chip structure on the second chip structure,
wherein the second chip structure includes:
a base substrate,
a second substrate having a lower surface opposing an upper surface of the base substrate,
peripheral circuit transistors disposed on the lower surface of the second substrate,
a second lower wiring structure disposed between the upper surface of the base substrate and the lower surface of the second substrate and including a second lower wiring layer electrically connected to the peripheral circuit transistors,
second through-vias extending through the second substrate and electrically connected to the second lower wiring layer,
a second upper wiring structure disposed on an upper surface of the second substrate and having a second upper wiring layer electrically connected to the second lower wiring layer through the second through-vias, and
second bonding pads disposed on an upper surface of the second upper wiring structure and electrically connected to the second upper wiring layer, and
wherein the first chip structure includes:
a first substrate having an upper surface on which a hydrogen-containing insulating layer is disposed,
a memory structure disposed on a lower surface of the first substrate,
a first lower wiring structure disposed on a lower surface of the memory structure, the first lower wiring structure including a first lower wiring layer electrically connected to the memory structure, wherein the first lower wiring structure is bonded to the second upper wiring structure,
first bonding pads disposed on a lower surface of the first lower wiring structure and electrically connected to the first lower wiring layer, wherein the first bonding pads are bonded to the second bonding pads,
first through-vias extending through the first substrate and electrically connected to the memory structure, and
a first upper wiring structure disposed on the first substrate and having a first upper wiring layer electrically connected to the memory structure through the first through-vias.

16. The semiconductor device of claim 15, wherein the hydrogen-containing insulating layer is disposed on the upper surface of the first substrate.

17. (canceled)

18. The semiconductor device of claim 16, wherein the hydrogen-containing insulating layer is disposed on the upper surface of the first substrate and has a flat upper surface.

19. The semiconductor device of claim 18, further comprising:
a barrier insulating film disposed between the hydrogen-containing insulating layer and the first upper wiring structure.

20. (canceled)

21. The semiconductor device of claim 15, wherein the memory structure includes a memory cell structure disposed below the lower surface of the first substrate and a data storage structure disposed below the memory cell structure.

22. The semiconductor device of claim 15, wherein the upper surface of the second upper wiring structure is coplanar with an upper surface of the second bonding pads, the lower surface of the first lower wiring structure is coplanar with a lower surface of the first bonding pads, and the upper surface of the second upper wiring structure is bonded to the lower surface of the first lower wiring structure.

23. (canceled)

24. (canceled)

25. (canceled)

26. (canceled)

27. (canceled)
